(19) United States
(12) Patent Application Publication
(10) Pub. No.: US 2012/0261739 A1
(43) Pub. Date: Oct. 18, 2012

(54) SEMICONDUCTOR DEVICE AND FABRICATION METHOD THEREOF

(75) Inventors: I-CHEN YANG, Hsinchu (TW); Yao-Wen Chang, Hsinchu (TW); Tao-Cheng Lu, Hsinchu (TW)

(73) Assignee: MACRONIX International Co., Ltd., Hsinchu (TW)

(21) Appl. No.: 13/088,240

(22) Filed: Apr. 15, 2011

(51) Int. Cl. H01L 29/788; H01L 21/336; H01L 29/78

(52) U.S. Cl. 257/316; 257/330; 438/259; 257/E29.262; 257/E29.3; 257/E21.41

(57) ABSTRACT

A semiconductor device including a first doped region of a first conductivity type, a second doped region of a second conductivity type, a gate, and a dielectric layer is provided. The first doped region is located in a substrate and has a trench. The second doped region is located at the bottom of the trench to separate the first doped region into a source doped region and a drain doped region. A channel region is located between the source doped region and the drain doped region. The gate is located in the trench. The dielectric layer covers the sidewall and the bottom of the trench and separates the gate and the substrate.

### BACKGROUND OF THE INVENTION

1. Field of the Invention

The invention generally relates to a semiconductor device and a fabrication method thereof, and more particularly, to a non-volatile memory and a fabrication method thereof.

2. Description of Related Art

A non-volatile memory (for example, an electrically erasable programmable read-only memory (EEPROM)) can retain data stored therein even when no power is supplied. Besides, data programming, reading, and erasing operations can be repeatedly performed on a non-volatile memory. Therefore, non-volatile memory has been broadly applied in different personal computers and electronic devices.

Along with the rapid advancement of integrated circuit (IC) technologies, the demand for high device integration has been continuously increasing, and along with the decrease of linewidth, the affection of short channel effect has become more serious. In order to avoid the short channel effect, the depths and concentrations of the source doped region and the drain doped region have to be reduced as much as possible (i.e., lightly doped source doped region and drain doped region with shallow junction depths). However, this will result in increase in the resistances of the source doped region and the drain doped region and accordingly decrease in the read current of the memory component. As a result, the performance of the memory component will be affected. In addition, the increase in the resistances of the source doped region and the drain doped region will also result in decrease in the driving current of a logic component.

### SUMMARY OF THE INVENTION

Accordingly, the invention is directed to a semiconductor device, wherein the short channel effect is prevented and the resistances of the source doped region and the drain doped region are reduced.

The invention provides a semiconductor device including a substrate, a first doped region of a first conductivity type, a second doped region of a second conductivity type, a gate, and a dielectric layer. The first doped region of the first conductivity type is located in the substrate and has a trench. The second doped region of the second conductivity type is located at the bottom of the trench to separate the first doped region into a source doped region and a drain doped region. A channel region is located between the source doped region and the drain doped region. The gate is located in the trench. The dielectric layer is located between the gate and the substrate within the trench.

According to an embodiment of the invention, the source doped region or the drain doped region is extended from a spot on the bottom of the trench that is close to the base angle to the surface of the substrate along the sidewall of the trench.

According to an embodiment of the invention, the second doped region includes a first region and a second region having different depths, wherein the area of the second region that is farther away from the bottom of the trench is greater than the area of the first region that is closer to the bottom of the trench, so that the source doped region or the drain doped region presents a stepped shape.

According to an embodiment of the invention, the semiconductor device further includes a spacer, wherein the spacer is located between the dielectric layer on the sidewall of the trench and the substrate.

According to an embodiment of the invention, the second doped region is extended from the bottom of the trench to a spot on the sidewall of the trench that is close to the base angle so that the source doped region or the drain doped region does not cover the bottom of the trench or the base angle but is extended from the sidewall of the trench to the surface of the substrate.

According to an embodiment of the invention, the semiconductor device further includes a semiconductor layer, wherein the semiconductor layer completely covers and is in contact with the source doped region or the drain doped region.

According to an embodiment of the invention, the semiconductor layer includes one or a combination of a doped single-crystal silicon layer, a doped polysilicon layer, a doped epi-silicon layer, and a doped GeSi layer.

According to an embodiment of the invention, the semiconductor device further includes a metal silicide layer, wherein the metal silicide layer is located on the semiconductor layer.

According to an embodiment of the invention, the semiconductor device further includes a hard mask layer, wherein the hard mask layer is located on the semiconductor layer.

According to an embodiment of the invention, the semiconductor device further includes a hard mask layer, wherein the hard mask layer is located on the source doped region or the drain doped region.

According to an embodiment of the invention, the dielectric layer is further extended onto the source doped region or the drain doped region.

According to an embodiment of the invention, the gate is further extended above and covers the source doped region or the drain doped region.

According to an embodiment of the invention, the semiconductor device is a metal-oxide semiconductor field-effect transistor (MOSFET), and the dielectric layer is a gate dielectric layer.

According to an embodiment of the invention, the semiconductor device is a non-volatile memory cell, and the dielectric layer is a tunnelling dielectric layer.

According to an embodiment of the invention, the gate is a floating gate, and the semiconductor device further includes a control gate and an inter-gate dielectric layer. The control gate is located above the floating gate. The inter-gate dielectric layer is located between the floating gate and the control gate.

According to an embodiment of the invention, the floating gate is protruded from the surface of the substrate.

According to an embodiment of the invention, the floating gate, the inter-gate dielectric layer, and the control gate are further extended above the source doped region or the drain doped region.

According to an embodiment of the invention, the surface of the floating gate is a flat surface or a surface with grooves.

According to an embodiment of the invention, the semiconductor device further includes a charge storage dielectric layer, wherein the charge storage dielectric layer is located between the tunnelling dielectric layer and the gate.

According to an embodiment of the invention, the charge storage dielectric layer is further extended above the source doped region or the drain doped region.

According to an embodiment of the invention, the semiconductor device further includes a top dielectric layer, wherein the top dielectric layer is located between the charge storage dielectric layer and the gate.

The invention provides a fabrication method of a semiconductor device. The fabrication method includes following steps. A substrate is provided, and a first doped region of a first conductivity type is formed in the substrate. Then, a portion of the first doped region is removed to form a trench in the first doped region. A second doped region of a second conductivity type is formed at the bottom of the trench to separate the first doped region into a source doped region and a drain doped region. A gate is formed in the trench, and a dielectric layer is formed between the gate and the substrate within the trench.

According to an embodiment of the invention, the fabrication method further includes forming a spacer on the sidewall of the trench.

According to an embodiment of the invention, the formation method of the second doped region includes performing a single ion implantation process by using the spacer as a mask, so as to extend the source doped region and the drain doped region from the surface of the substrate to a spot on the bottom of the trench that is close to the base angle along the sidewall of the trench.

According to an embodiment of the invention, the formation method of the second doped region includes performing a first ion implantation process and a second ion implantation process by using the spacer as a mask, wherein the energy of the second ion implantation process is higher than the energy of the first ion implantation process so that the area of a region formed through the second ion implantation process that is farther away from the bottom of the trench is greater than the area of a region formed through the first ion implantation process that is closer to the bottom of the trench.

According to an embodiment of the invention, the fabrication method further includes removing the spacer after forming the second doped region and before forming the dielectric layer.

According to an embodiment of the invention, the formation method of the second doped region includes performing an ion implantation process by using the trench as a mask, so as to extend the second doped region from the bottom of the trench to a spot on the sidewall of the trench that is close to the base angle.

According to an embodiment of the invention, the fabrication method further includes forming a semiconductor layer on the substrate before forming the trench, wherein the semiconductor layer is in contact with the first doped region.

According to an embodiment of the invention, the fabrication method further includes forming a hard mask layer on the semiconductor layer after forming the semiconductor layer and before forming the trench.

According to an embodiment of the invention, the fabrication method further includes removing the hard mask layer after forming the trench and before forming the dielectric layer.

According to an embodiment of the invention, the fabrication method further includes removing the hard mask layer after forming the gate.

According to an embodiment of the invention, the fabrication method further includes forming a metal silicide layer on the semiconductor layer after removing the hard mask layer.

According to an embodiment of the invention, the fabrication method further includes forming a hard mask layer on the substrate before forming the trench.

According to an embodiment of the invention, the fabrication method further includes removing the hard mask layer before forming the dielectric layer.

According to an embodiment of the invention, the semiconductor device is a MOSFET, and the dielectric layer is a gate dielectric layer.

According to an embodiment of the invention, the semiconductor device is a non-volatile memory cell, and the dielectric layer is a tunnelling dielectric layer.

According to an embodiment of the invention, the gate is a floating gate, and the fabrication method further includes forming a control gate on the floating gate and forming an inter-gate dielectric layer between the floating gate and the control gate.

According to an embodiment of the invention, the fabrication method further includes following steps. A hard mask layer is formed on the substrate before forming the trench, and the upper surface of the gate in the trench is made to be lower than the upper surface of the hard mask layer, so as to expose the sidewall of the hard mask layer. A gate material layer is formed on the sidewall of the hard mask layer and the gate, so as to form a floating gate having a groovy surface. A control gate is formed on the floating gate, and an inter-gate dielectric layer is formed between the floating gate and the control gate.

According to an embodiment of the invention, the floating gate, the inter-gate dielectric layer, and the control gate are further extended above the source doped region and the drain doped region.

According to an embodiment of the invention, the fabrication method further includes forming a charge storage dielectric layer between the tunnelling dielectric layer and the gate.

According to an embodiment of the invention, the charge storage dielectric layer is further extended above the source doped region and the drain doped region.

According to an embodiment of the invention, the fabrication method further includes forming a top dielectric layer between the charge storage dielectric layer and the gate.

The semiconductor device in the invention can prevent the production of short channel effect and can reduce the resistances of the source doped region and the drain doped region.

It is to be understood that both the foregoing general description and the following detailed description are exemplary, and are not intended to limit the scope of the invention. These and other exemplary embodiments, features, aspects, and advantages of the invention will be described and become more apparent from the detailed description of exemplary embodiments when read in conjunction with accompanying drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 illustrates a semiconductor device according to an embodiment of the invention.

FIGS. 2A-2D-1 are cross-sectional views illustrating a fabrication method of a silicon nitride read-only memory (ROM) according to a first embodiment of the invention.

FIG. 2D-2 is a cross-sectional view of a silicon nitride ROM according to a second embodiment of the invention.

FIG. 2D-3 is a cross-sectional view of a silicon nitride ROM according to a third embodiment of the invention.

FIGS. 3A-3D-1 are cross-sectional views illustrating a fabrication method of a silicon nitride ROM according to a fourth embodiment of the invention.

FIG. 3D-2 is a cross-sectional view of a silicon nitride ROM according to a fifth embodiment of the invention.

FIG. 3D-3 is a cross-sectional view of a silicon nitride ROM according to a sixth embodiment of the invention.

FIGS. 4A-4D-1 are cross-sectional views illustrating a fabrication method of a silicon nitride ROM according to a seventh embodiment of the invention.

FIG. 4D-2 is a cross-sectional view of a silicon nitride ROM according to an eighth embodiment of the invention.

FIG. 4D-3 is a cross-sectional view of a silicon nitride ROM according to a ninth embodiment of the invention.

FIGS. 5A-5D-1 are cross-sectional views illustrating a fabrication method of a silicon nitride ROM according to a tenth embodiment of the invention.

FIG. 5D-2 is a cross-sectional view of a silicon nitride ROM according to an eleventh embodiment of the invention.

FIG. 5D-3 is a cross-sectional view of a silicon nitride ROM according to a twelfth embodiment of the invention.

FIGS. 6A-6F are cross-sectional views illustrating a fabrication method of a flash memory cell according to a thirteenth embodiment of the invention.

FIGS. 7A-7F are cross-sectional views illustrating a fabrication method of a flash memory cell according to a fourteenth embodiment of the invention.

FIGS. 8A-8F are cross-sectional views illustrating a fabrication method of a flash memory cell according to a fifteenth embodiment of the invention.

FIGS. 9A-9F are cross-sectional views illustrating a fabrication method of a flash memory cell according to a sixteenth embodiment of the invention.

FIGS. 10A-10F are cross-sectional views illustrating a fabrication method of a flash memory cell according to a seventeenth embodiment of the invention.

FIGS. 11A-11F are cross-sectional views illustrating a fabrication method of a flash memory cell according to an eighteenth embodiment of the invention.

FIGS. 12A-12F are cross-sectional views illustrating a fabrication method of a metal-oxide semiconductor field-effect transistor (MOSFET) according to a nineteenth embodiment of the invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

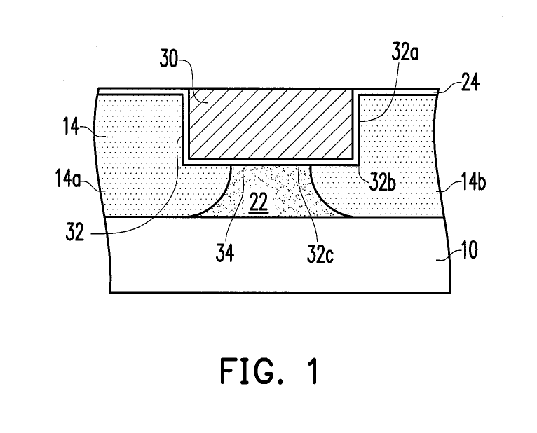

FIG. 1 illustrates a semiconductor device provided by the invention.

Referring to FIG. 1A, the semiconductor device provided by an embodiment of the invention includes a substrate 10, a first doped region 14 of a first conductivity type, a second doped region 22 of a second conductivity type, a gate 30, and a dielectric layer 24. The first doped region 14 is located in the substrate 10, and has a trench 32. The second doped region 22 is located at the bottom 32c of the trench 32 so that the first doped region 14 is separated into a source doped region 14a and a drain doped region 14b. A channel region 34 is located between the source doped region 14a and the drain doped region 14b. The gate 30 is located in the trench 32. The dielectric layer 24 covers the sidewall 32a and the bottom 32c of the trench 32 and separates the gate 30 and the substrate 10.

In an embodiment of the invention, the gate 30 is buried in the substrate 10, and the source doped region 14a and the drain doped region 14b with raised effect are fabricated through the position change of the gate 30 in the perpendicular direction. Because the portions of the source doped region 14a and the drain doped region 14b that are located below the gate 30 are very shallow, a shallow junction depth is achieved and accordingly the production of short channel effect is avoided. On the other hand, because the source doped region 14a and the drain doped region 14b are further extended upwards to cover the sidewall of the gate 30, the source doped region 14a and the drain doped region 14b may be considered a raised source and drain and have a reduced resistance.

The semiconductor device may be a metal-oxide semiconductor field-effect transistor (MOSFET) or a non-volatile memory cell (for example, a flash memory cell or a silicon nitride read-only memory (ROM). If the semiconductor device is a MOSFET, the dielectric layer 24 is a gate dielectric layer, and if the semiconductor device is a non-volatile memory cell, the dielectric layer 24 is a tunnelling dielectric layer.

The gate 30 may be located only in the trench 32 or extended upwards to be protruded out of the surface of the substrate 10, or the gate 30 may even be extended sidewards to cover the substrate 10. If the semiconductor device is a flash memory cell, the gate 30 is a floating gate, and if the semiconductor device is a silicon nitride ROM, the gate 30 is connected to a word line.

The source doped region 14a and the drain doped region 14b may be extended from a spot on the bottom 32c of the trench 32 that is close to the base angle 32b to the surface of the substrate 10 along the sidewall 32a. Or, the source doped region 14a and the drain doped region 14b may not cover the bottom 32c of the trench 32 or the base angle 32b but be extended from the sidewall 32a of the trench 32 to the surface of the substrate 10.

Several embodiments of the invention will be described below. However, these embodiments are not intended to limit the scope of the invention.

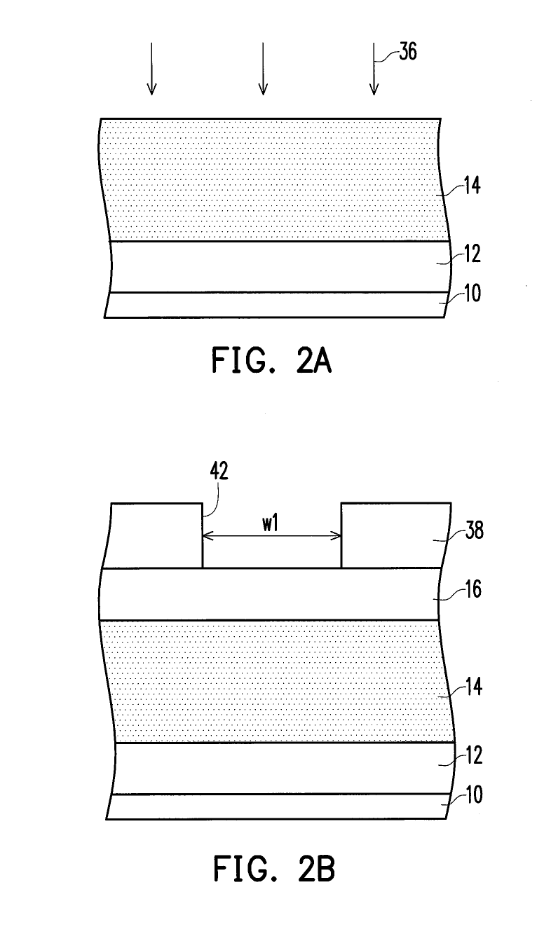

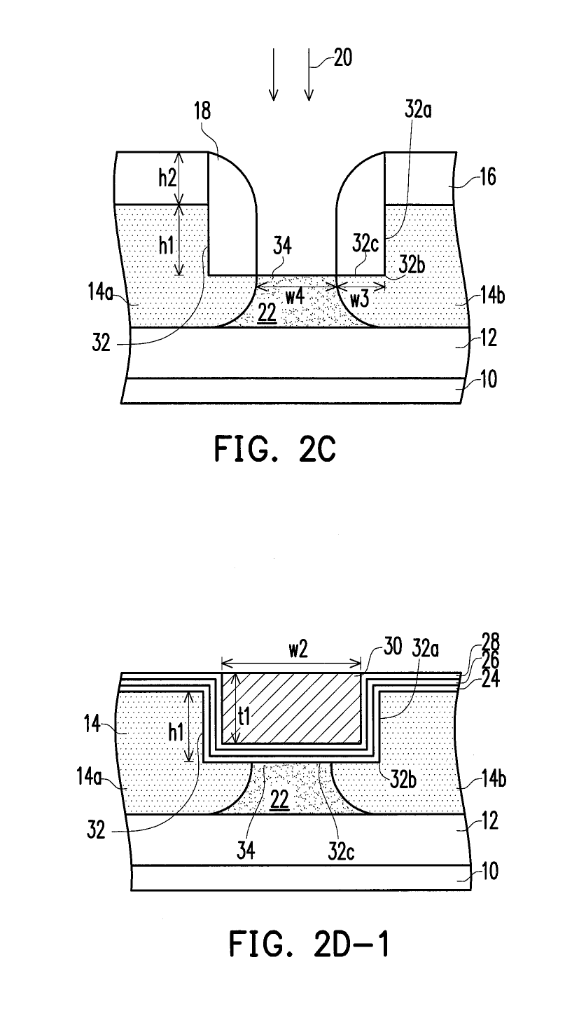

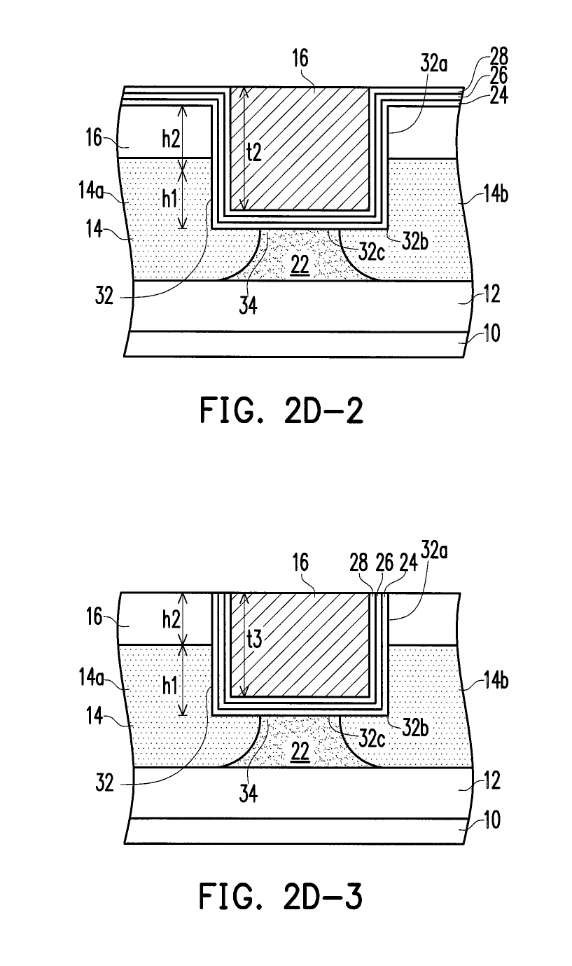

FIGS. 2A-2D-1 are cross-sectional views illustrating a fabrication method of a silicon nitride ROM according to a first embodiment of the invention.

Referring to FIG. 2A, a well 12 is formed in the substrate 10, and the first doped region 14 is formed within the well 12. The substrate 10 may be a semiconductor substrate, a compound semiconductor substrate, or a semiconductor over insulator (SOI) substrate. The semiconductor may be composed of IVA group atoms, such as silicon or germanium. For example, the semiconductor may be a silicon wafer or epitaxial silicon. The compound semiconductor may be composed of IVA group atoms, such as silicon carbide or silicon germanium. The substrate 10 may be doped, and the dopant may have a second conductivity type. Herein the second conductivity type may be P type or N type. P-type dopant may be IIIA group ions, such as boron. N-type dopant may be VA group ions, such as arsenic ions or phosphor ions.

The well 12 is formed by first performing a single ion implantation process or multiple ion implantation processes and then an annealing process. The dopant used for forming the well 12 has a conductivity type different from that of the flash memory cell. If the channel conductivity type of the flash memory cell is the first conductivity type, the dopant of the well 12 is then ions of the second conductivity type. Namely, if the flash memory cell is a P-type channel, the well 12 is then N-type, and if the flash memory cell is an N-type channel, the well 12 is then P-type. In an embodiment, the well 12 is P-type, the implanted ions are boron ions, the energy of the ion implantation process may be about 50 KeV to about 500 KeV, and the dosage may be about 1×10¹²/cm² to about 3×10¹³/cm².

In an embodiment, the first doped region 14 may also be formed by first performing an ion implantation process 36 and then an annealing process. The dopant used for forming the first doped region 14 may be ions of the first conductivity type. The first conductivity type is different from the second conductivity type and which may be N-type or P-type. The first doped region 14 may be formed through an ion implantation process. The number of times (one or more) of performing the ion implantation process 36 is related to the concentrations and junction depths of the source doped region 14a and the drain doped region 14b (as shown in FIG. 2C) to be formed. In the present embodiment, because a semiconductor layer 40 (will be described in following embodiment) is not formed above the substrate 10 to reduce the contact resistance, first doped regions 14 of different depths and concentrations can be formed through multiple ion implantation processes. In an embodiment, the first doped region 14 is N-type and is formed through a single ion implantation process 36, wherein the dopant may be arsenic ions, the energy of the ion implantation process may be about 15 KeV to about 40 KeV, and the dosage may be about 1×10¹⁵/cm² to about 4×10¹⁵/cm². In another embodiment, the first doped region 14 is N-type and is formed through two ion implantation processes 36, and the dopant used in both ion implantation processes 36 is arsenic ions. Herein the energy of the first ion implantation process may be about 5 KeV to about 15 KeV, the dosage thereof may be about 1×10¹⁵/cm² to about 4×10¹⁵/cm², the energy of the second ion implantation process may be 15 KeV to 50 KeV, and the dosage thereof may be about 3×10¹⁴/cm² to about 2×10¹⁵/cm². Accordingly, referring to FIG. 2D-1, the doping concentration of the source doped region 14a and the drain doped region 14b close to the surface of the substrate 10 is higher than that below the trench 32, so that a reduced contact resistance and a shallow junction depth can be achieved at the same time.

Next, referring to FIG. 2B, a hard mask layer 16 is formed on the substrate 10. The hard mask layer 16 may be composed of one, two, or more material layers. The hard mask layer 16 may be made of one or a combination of silicon oxide, silicon nitride, and silicon oxynitride. The hard mask layer 16 may be formed through physical vapour deposition (PVD) or chemical vapour deposition (CVD). The thickness of the hard mask layer 16 may be between about 300 Å and about 1000 Å.

Thereafter, a photoresist layer 38 having an opening 42 is formed on the hard mask layer 16. The photoresist layer 38 may be positive photoresist or negative photoresist. The opening 42 of the photoresist layer 38 exposes the hard mask layer 16. The width w1 of the opening 42 is slightly greater than the width w2 of the gate 30 (as shown in FIG. 2D-1) to be formed. In an embodiment, the width w1 of the opening 42 may be between about 550 Å and about 1500 Å.

Next, referring to FIG. 2C, the hard mask layer 16 exposed by the opening 42 is removed by using the photoresist layer 38 as a mask, and a portion of the substrate 10 below the hard mask layer 16 is also removed to form the trench 32 in the hard mask layer 16 and the first doped region 14 of the substrate 10. After that, the photoresist layer 38 is removed. The hard mask layer 16 and the portion of the substrate 10 below the hard mask layer 16 may be removed through an etching process, such as a dry etching process. The sidewall 32a of the trench 32 may be a vertical surface, a tilted surface, or a curved surface. The base angle 32b of the trench 32 may be but is not limited to a vertical corner, and which may also be a rounded corner or a polygonal corner. The depth h1 of the trench 32 in the substrate 10 may be between about 400 Å and about 700 Å.

Next, a spacer 18 is formed on the sidewall 32a of the trench 32. The spacer 18 may be formed by forming a spacer material layer on the hard mask layer 16 and the surface of the trench 32 and then removing portion of the spacer material layer through an anisotropic etching process. The spacer 18 may be composed of one, two, or more material layers. The spacer 18 may be made of one or a combination of silicon oxide, silicon nitride, and silicon oxynitride. After that, the second doped region 22 is formed in the substrate 10 exposed by the spacer 18 at the bottom 32c of the trench 32, and the second doped region 22 is extended downwards from the first doped region 14 to the well 12 to separate the first doped region 14 into the source doped region 14a and the drain doped region 14b. The source doped region 14a and the drain doped region 14b are extended from a spot on the bottom 32c of the trench 32 that is close to the base angle 32b to the surface of the substrate 10 along the sidewall 32a. A channel region 34 is formed between the source doped region 14a and the drain doped region 14b. The width of the channel region 34 is related to the width of the spacer 18. The smaller/greater the width w3 of the spacer 18 is, the greater/smaller the width w4 of the channel region 34 will be. In an embodiment, the second doped region 22 may be formed through an ion implantation process 20 by using the hard mask layer 16 and the spacer 18 as masks. The dopant used for forming the second doped region 22 may be ions of the second conductivity type. Herein the second conductivity type may be P-type or N-type. In an embodiment, the first doped region 14 is N-type while the second doped region 22 is P-type. The ions implanted into the second doped region 22 may be BF₂, the energy of the ion implantation process may be about 1 KeV to about 15 KeV, and the dosage may be about 5×10¹³/cm² to about 9×10¹⁴/cm².

Thereafter, referring to FIG. 2D-1, the spacer 18 is removed. The spacer 18 may be removed through an etching process, such as a wet etching process or a dry etching process. Next, the hard mask layer 16 is removed. The hard mask layer 16 may be removed through an etching process, such as a wet etching process or a dry etching process.

After that, a tunnelling dielectric layer 24, a charge storage dielectric layer 26, and a top dielectric layer 28 are formed on the substrate 10 and the sidewall 32a and the bottom 32c of the trench 32. The tunnelling dielectric layer 24 may be composed of a single material layer, wherein the single material layer may be made of a low dielectric constant material or a high dielectric constant material. A low dielectric constant material is a dielectric material having its dielectric constant lower than 4, such as silicon oxide or silicon oxynitride (SiOₓN_{y}), wherein x and y may be any possible value. A high dielectric constant material is a dielectric material having its dielectric constant higher than 4, such as HfAlO, HfO₂, Al₂O₃, or Si₃N₄. The tunnelling dielectric layer 24 may also adopt a stacked double-layer structure or a stacked multi-layer structure according to the band-gap engineering (BE) theory so that the injection current thereof, accordingly the programming rate, can be increased. Herein the stacked double-layer structure may be fabricated by using a low dielectric constant material and a high dielectric constant material (indicated as low dielectric constant material/high dielectric constant material), such as silicon oxide/HfSiO, silicon oxide/HfO₂, or silicon oxide/silicon nitride. The stacked multi-layer structure may be fabricated by using a low dielectric constant material, a high dielectric constant material, and a low dielectric constant material (indicated as low dielectric constant material/high dielectric constant material/low dielectric constant material), such as silicon oxide/silicon nitride/silicon oxide or silicon oxide/Al₂O₃/silicon oxide. The charge storage dielectric layer 26 may be made of silicon nitride or HfO₂. The top dielectric layer 28 is composed of a single material layer. Herein the single material layer may be made of a low dielectric constant material or a high dielectric constant material. Herein a low dielectric constant material is a dielectric material having its dielectric constant lower than 4, such as silicon dioxide or silicon oxynitride. A high dielectric constant material is a dielectric material having its dielectric constant higher than 4, such as HfAlO, Al₂O₃, Si₃N₄, or HfO₂. The top dielectric layer 28 may also adopt a stacked double-layer structure or a stacked multi-layer structure according to the BE theory so that the injection current thereof; accordingly the programming rate or the erasing rate, can be increased. The stacked double-layer structure may be fabricated by using a high dielectric constant material and a low dielectric constant material (indicated as high dielectric constant material/low dielectric constant material), such as silicon nitride/silicon oxide. The stacked multi-layer structure may be fabricated by using a low dielectric constant material, a high dielectric constant material, and a low dielectric constant material (indicated as low dielectric constant material/high dielectric constant material/low dielectric constant material), such as silicon oxide/silicon nitride/silicon oxide or silicon oxide/Al₂O₃/silicon oxide.

Thereafter, the gate 30 connected to a word line is formed in the remaining space of the trench 32. The gate 30 may be made of doped polysilicon or metal or have a stacked structure made of doped polysilicon and metal. The gate 30 may be formed by forming a gate material layer on the substrate 10 to cover the top dielectric layer 28 and fill up the trench 32 and then removing the gate material layer outside the trench 32 and on the top dielectric layer 28, wherein the gate material layer may be removed through an etching process or a chemical mechanical polishing (CMP) process.

In the embodiment described above, the annealing process of the source doped region 14a and the drain doped region 14b (the first doped region 14) is performed before the tunnelling dielectric layer 24 and the gate 30 are formed. Thus, the stability of the tunnelling dielectric layer 24 (especially a tunnelling dielectric layer made of a material having a high dielectric constant) and the gate 30 (especially a metal gate) won't be affected by the annealing process of the source doped region 14a and the drain doped region 14b (the first doped region 14).

The silicon nitride ROM illustrated in FIG. 2D-1 includes a substrate 10, a well 12, a first doped region 14 of a first conductivity type, a second doped region 22 of a second conductivity type, a gate 30, a tunnelling dielectric layer 24, a charge storage dielectric layer 26, and a top dielectric layer 28. The well 12 and the first doped region 14 are located in the substrate 10, and the first doped region 14 has a trench 32. The second doped region 22 is located at the bottom 32c of the trench 32 so that the first doped region 14 is separated into a source doped region 14a and a drain doped region 14b. A channel region 34 is located between the source doped region 14a and the drain doped region 14b. The gate 30 is buried into the trench 32 of the substrate 10, and the thickness t1 thereof is approximately the same as the depth h1 of the trench 32 in the substrate 10. The thickness t1 of the gate 30 may be between about 400 Å and about 700 Å. The sidewall 32a of the gate 30 may be a vertical surface, a tilted surface, or a curved surface. The base angle 32b of the gate 30 may be but is not limited to a vertical corner, and which may also be a rounded corner or a polygonal corner. The tunnelling dielectric layer 24, the charge storage dielectric layer 26, and the top dielectric layer 28 cover the sidewall 32a and the bottom 32c of the trench 32, separate the gate 30 and the substrate 10, and are extended above and in direct contact with the source doped region 14a and the drain doped region 14b.

According to an embodiment of the invention, the gate 30 is buried into the trench 32 of the substrate 10 so that the source doped region 14a and the drain doped region 14b are not only located below the gate 30 but extended to cover the sidewall 32a of the gate 30. Because the portions of the source doped region 14a and the drain doped region 14b below the gate 30 are very shallow, a shallow junction depth is achieved, and accordingly the production of short channel effect is avoided. On the other hand, because the source doped region 14a and the drain doped region 14b are further extended to cover the sidewall 32a of the gate 30, the source doped region 14a and the drain doped region 14b can be considered a raised source and drain and have a reduced resistance.

It should be mentioned that in the present embodiment, the gate 30 is buried into the substrate 10 and the source doped region 14a and the drain doped region 14b are also formed in the substrate 10, so that the source doped region 14a and the drain doped region 14b with the raised effect are formed through the position change of the gate 30 in the vertical direction but not through an epitaxial layer additionally formed by directly forming the gate 30 on the surface of the substrate 10. Thus, in the invention, the source doped region 14a and the drain doped region 14b with the raised effect are formed by simply doping the substrate 10, wherein the portions thereof below and surrounding the gate 30 are made of the same material, and there is no any junction between these two portions.

FIG. 2D-2 is a cross-sectional view of a silicon nitride ROM according to a second embodiment of the invention.

Referring to FIG. 2D-2, the spacer 18 is also removed after the fabrication of the silicon nitride ROM is partially completed through the fabrication method illustrated in FIGS. 2A-2C. However, the hard mask layer 16 is not removed. Instead, the tunnelling dielectric layer 24, the charge storage dielectric layer 26, and the top dielectric layer 28 are directly formed on the hard mask layer 16. After that, the gate 30 connected to a word line is formed in the remaining space of the trench 32.

The silicon nitride ROM illustrated in FIG. 2D-2 has a similar structure as the silicon nitride ROM illustrated in FIG. 2D-1. However, in the silicon nitride ROM illustrated in FIG. 2D-2, the tunnelling dielectric layer 24, the charge storage dielectric layer 26, and the top dielectric layer 28 cover the sidewall 32a and the bottom 32c of the trench 32, separate the gate 30 and the substrate 10, and are extended onto the hard mask layer 16 above the source doped region 14a and the drain doped region 14b. The gate 30 is located in the trench 32 of the substrate 10 and the hard mask layer 16. If the thicknesses of the tunnelling dielectric layer 24, the charge storage dielectric layer 26, and the top dielectric layer 28 on the hard mask layer 16 are equivalent to the thicknesses of the tunnelling dielectric layer 24, the charge storage dielectric layer 26, and the top dielectric layer 28 at the bottom 32c of the trench 32, the thickness of the gate 30 is then approximately the same as the depth h1+h2 of the trench 32 in the substrate 10 and the hard mask layer 16. If as the trench 32 in the substrate 10 shown in FIG. 2D-1 and FIG. 2D-2 has the same depth h1, since the trench 32 of the silicon nitride ROM in FIG. 2D-2 is further extended upwards to the hard mask layer 16 therefore has a depth h1+h2 (which is greater than the depth h1 of the trench 32 in FIG. 2D-1), the thickness t2 of the gate 30 in the silicon nitride ROM illustrated in FIG. 2D-2 is greater than the thickness t1 of the gate 30 in the silicon nitride ROM illustrated in FIG. 2D-1. In other words, if the thickness t2 of the gate 30 in FIG. 2D-2 is equivalent to the thickness t1 of the gate 30 in FIG. 2D-1, the trench 32 in the substrate 10 illustrated in FIG. 2D-2 can be formed to have a depth h1 slightly shallower than that of the trench 32 in the substrate 10 illustrated in FIG. 2D-1.

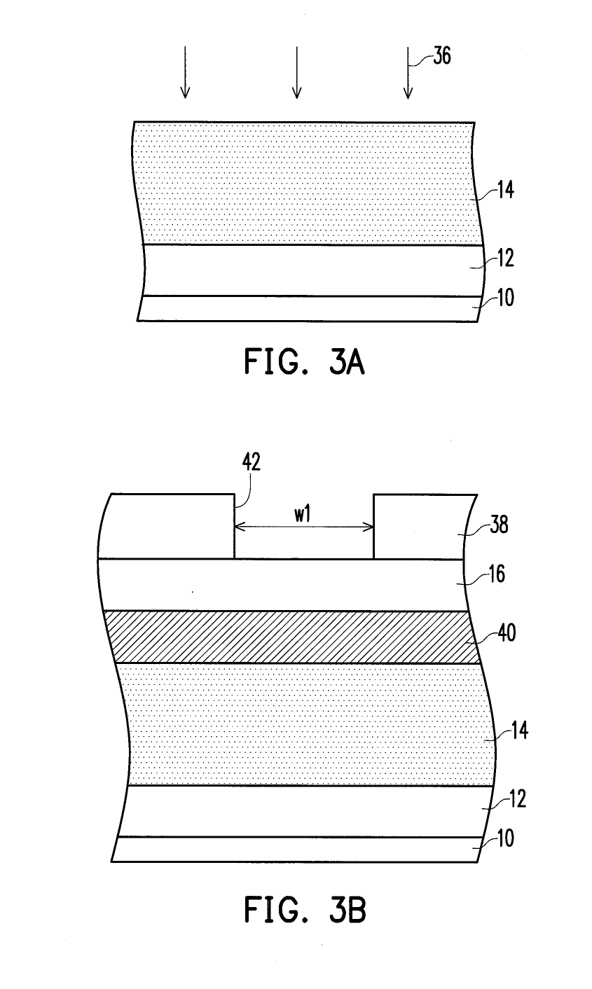

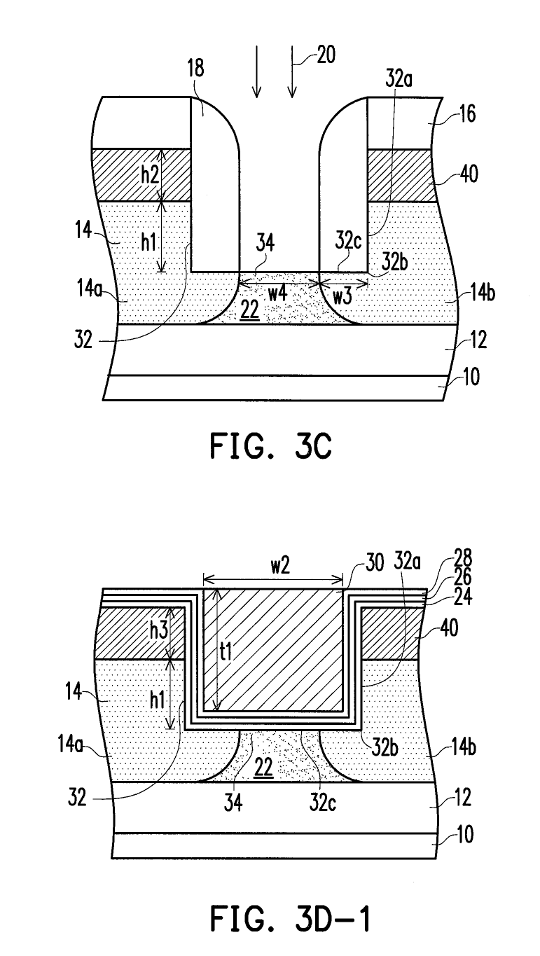

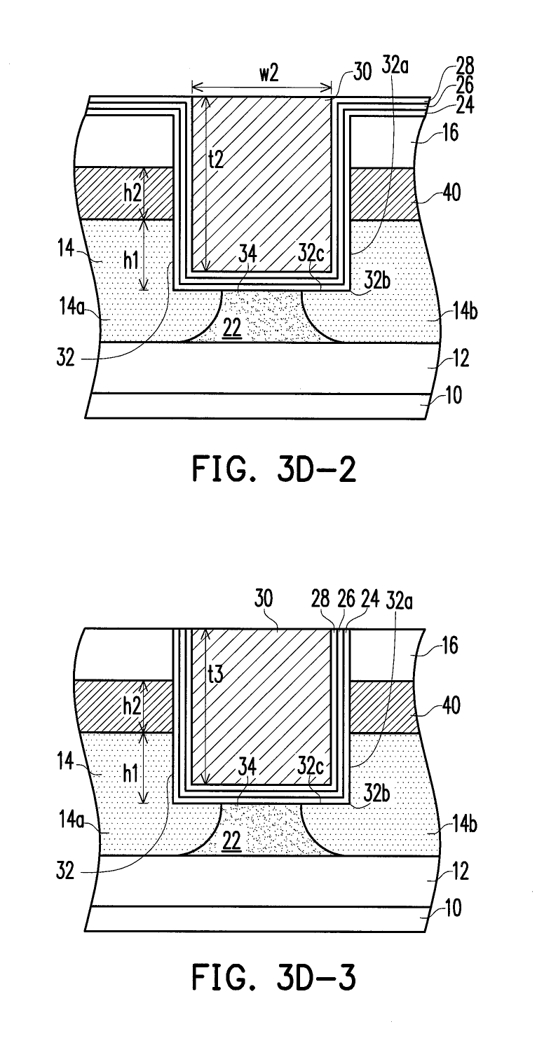

FIG. 2D-3 is a cross-sectional view of a silicon nitride ROM according to a third embodiment of the invention.

Referring to FIG. 2D-3, the spacer 18 is also removed after the fabrication of the silicon nitride ROM is partially completed through the fabrication method illustrated in FIGS. 2A-2C. However, the hard mask layer 16 is not removed. Instead, the tunnelling dielectric layer 24, the charge storage dielectric layer 26, and the top dielectric layer 28 are directly formed on the hard mask layer 16 and the sidewall 32a and the bottom 32c of the trench 32, and the gate 30 connected to a word line is formed in the remaining space of the trench 32. However, the tunnelling dielectric layer 24, the charge storage dielectric layer 26, and the top dielectric layer 28 on the hard mask layer 16 are removed before the gate 30 is formed. Foregoing layers may be removed through an etching process or a CMP process by using the hard mask layer 16 as an etch stop layer.

The silicon nitride ROM illustrated in FIG. 2D-3 has a similar structure as the silicon nitride ROM illustrated in FIG. 2D-2. However, in the silicon nitride ROM illustrated in FIG. 2D-3, the tunnelling dielectric layer 24, the charge storage dielectric layer 26, and the top dielectric layer 28 only cover the sidewall 32a and the bottom 32c of the trench 32 to separate the gate 30 and the substrate 10 but are not extended onto the hard mask layer 16 above the source doped region 14a and the drain doped region 14b. Thus, in this structure, the surface of the hard mask layer 16 is exposed. The thickness t3 of the gate 30 is approximately the depth h1+h2 of the trench 32 in the substrate 10 and the hard mask layer 16 minus the thicknesses of the tunnelling dielectric layer 24, the charge storage dielectric layer 26, and the top dielectric layer 28. In other words, if the thickness t3 of the gate 30 in FIG. 2D-3 is equivalent to the thickness t1 of the gate 30 in FIG. 2D-1, the trench 32 in the substrate 10 in FIG. 2D-3 can be formed to have a depth h1 slightly shallower than that of the trench 32 in the substrate 10 in FIG. 2D-1.

FIGS. 3A-3D-1 are cross-sectional views illustrating a fabrication method of a silicon nitride ROM according to a fourth embodiment of the invention. FIG. 3D-2 is a cross-sectional view of a silicon nitride ROM according to a fifth embodiment of the invention. FIG. 3D-3 is a cross-sectional view of a silicon nitride ROM according to a sixth embodiment of the invention.

Referring to FIGS. 3A-3D-1, a silicon nitride ROM is fabricated through the fabrication method illustrated in FIGS. 2A-2D-1. However, a semiconductor layer 40 is formed on the substrate 10 after forming the well 12 in the substrate 10 and the first doped region 14 in the well 12 and before forming the hard mask layer 16. The semiconductor layer 40 is patterned in the subsequent process for forming the trench 32, as shown in FIG. 3C. The patterned semiconductor layer 40 is retained and served as source and drain contact regions. The semiconductor layer 40 is doped, and the dopant in the semiconductor layer 40 has the same conductivity type as the source doped region 14a and the drain doped region 14b. The doping concentration of the semiconductor layer 40 is greater than or close to that of the source doped region 14a and the drain doped region 14b so that the contact resistance can be further reduced. The semiconductor layer 40 includes one or a combination of a doped single-crystal silicon layer, a doped polysilicon layer, a doped epi-silicon layer, and a doped GeSi layer. The dopant in the semiconductor layer 40 may be in-situ doped during the deposition process or doped through an ion implantation process after semiconductor deposition. In an embodiment, the dopant in the source doped region 14a and the drain doped region 14b is N-type, and the semiconductor layer 40 may be one or a combination of a doped single-crystal silicon layer with in-situ doped N-type ions, polysilicon with in-situ doped N-type ions, an epitaxial silicon layer with in-situ doped N-type ions, and silicon germanium doped with N-type ions. In another embodiment, the dopant in the source doped region 14a and the drain doped region 14b is P-type, and the semiconductor layer 40 may be one or a combination of a doped single-crystal silicon layer with in-situ doped P-type ions, silicon germanium with in-situ doped P-type ions, an epitaxial silicon layer with in-situ doped P-type ions, and polysilicon with in-situ doped P-type ions. The thickness of the gate 30 is related to the thickness of the semiconductor layer 40 and the depth h1 of the trench 32 in the substrate 10. Namely, the existence of the semiconductor layer 40 allows the depth h1 of the trench 32 in the substrate 10 to be reduced. In an embodiment, the depth h1 of the trench 32 in the substrate 10 may be between about 300 Å and about 500 Å, and the thickness of the semiconductor layer 40 may be between about 300 Å and about 500 Å. However, the invention is not limited thereto, and the depth h1 of the trench 32 in the substrate 10 and the thickness of the semiconductor layer 40 may be adjusted according to the thickness of the gate to be formed and the depth of the trench 32 in the substrate 10 in an actual application. In addition, the semiconductor layer 40 may be considered a raised source doped region or drain doped region. Accordingly, the source doped region 14a and the drain doped region 14b below the trench 32 can be fabricated with shallower junction depth.

Thereafter, the fabrication of the silicon nitride ROM is completed through the fabrication method illustrated in FIGS. 3B-3D-1.

The silicon nitride ROM illustrated in FIG. 3D-1 further includes a semiconductor layer 40 besides a substrate 10, a well 12, a first doped region 14 of a first conductivity type, a second doped region 22 of a second conductivity type, a gate 30, a tunnelling dielectric layer 24, a charge storage dielectric layer 26, and a top dielectric layer 28. The first doped region 14 is located in the substrate 10, and the semiconductor layer 40 and the first doped region 14 have a trench 32. The trench 32 has a depth h3 in the semiconductor layer 40 and a depth h1 in the first doped region 14. The second doped region 22 is located at the bottom 32c of the trench 32 so that the first doped region 14 is separated into a source doped region 14a and a drain doped region 14b. A channel region 34 is located between the source doped region 14a and the drain doped region 14b. The source doped region 14a and the drain doped region 14b are extended from the bottom 32c of the trench 32 to the sidewall 32a of the trench 32 along the base angle 32b so as to cover the sidewall of the gate 30. The semiconductor layer 40 is located on the source doped region 14a and the drain doped region 14b and cover the sidewall of the gate 30. In other words, the gate 30 is located in the semiconductor layer 40 and the trench 32 of the substrate 10. The thickness of the gate 30 is approximately equivalent to the depth h1+h3 of the trench 32 in the substrate 10 and the semiconductor layer 40 (if the thicknesses of the tunnelling dielectric layer 24, the charge storage dielectric layer 26, and the top dielectric layer 28 can be ignored). The tunnelling dielectric layer 24, the charge storage dielectric layer 26, and the top dielectric layer 28 cover the sidewall 32a and the bottom 32c of the trench 32, separate the gate 30 and the substrate 10, and are extended onto and in direct contact with the semiconductor layer 40 above the source doped region 14a and the drain doped region 14b. If the trench 32 in the substrate 10 illustrated in FIG. 3D-1 and FIG. 2D-1 has the same depth h1, because the trench 32 of the silicon nitride ROM in FIG. 3D-1 is further extended upwards to the semiconductor layer 40, the depth thereof is h1+h3. Accordingly, the thickness of the gate 30 in the silicon nitride ROM illustrated in FIG. 3D-1 is greater than that of the gate 30 in the silicon nitride ROM illustrated in FIG. 2D-1.

Similarly, the silicon nitride ROMs illustrated in FIG. 3D-2 and FIG. 3D-3 are respectively similar to those illustrated in FIG. 2D-2 and FIG. 2D-3, and the difference is also that a semiconductor layer 40 is formed on the substrate 10 after forming the well 12 in the substrate 10 and the first doped region 14 within the well 12 and before forming the hard mask layer 16 and is served as the source and drain contact regions.

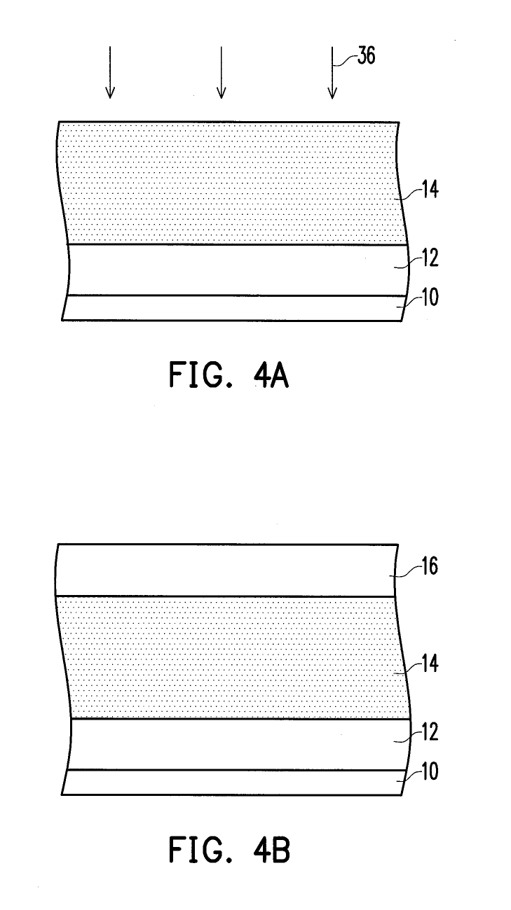

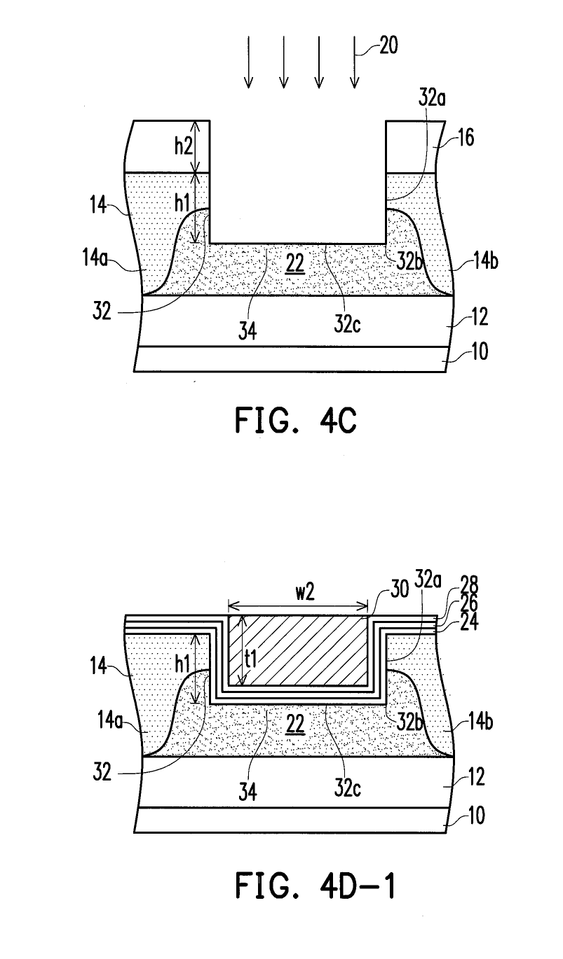

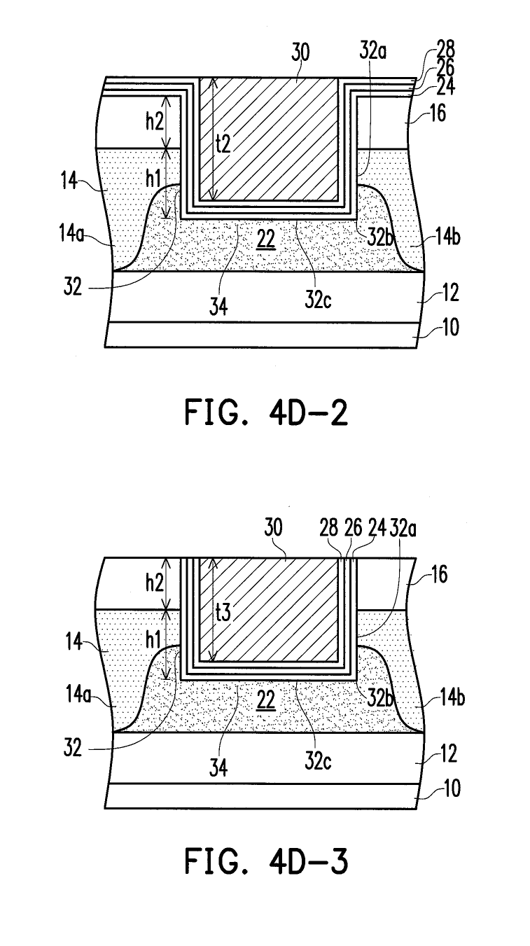

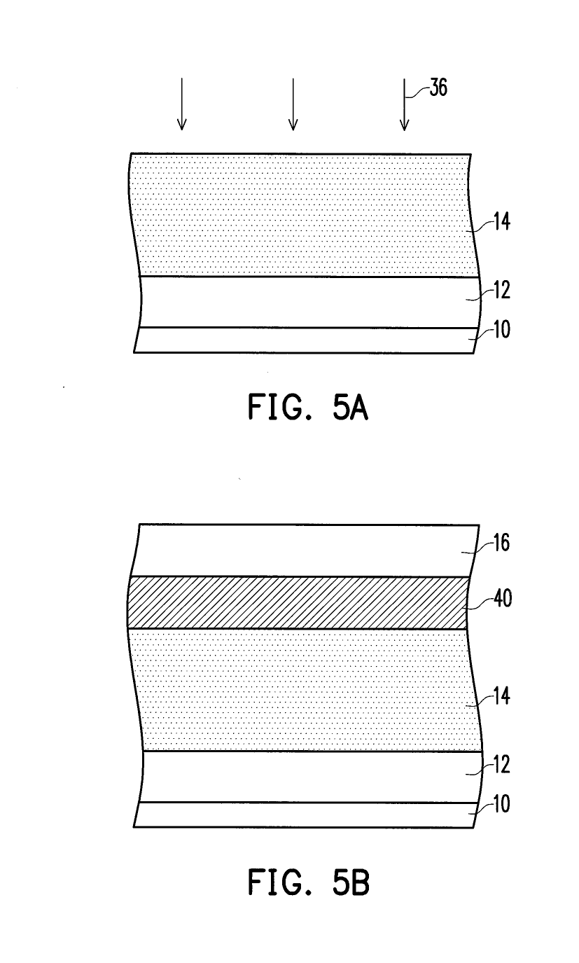

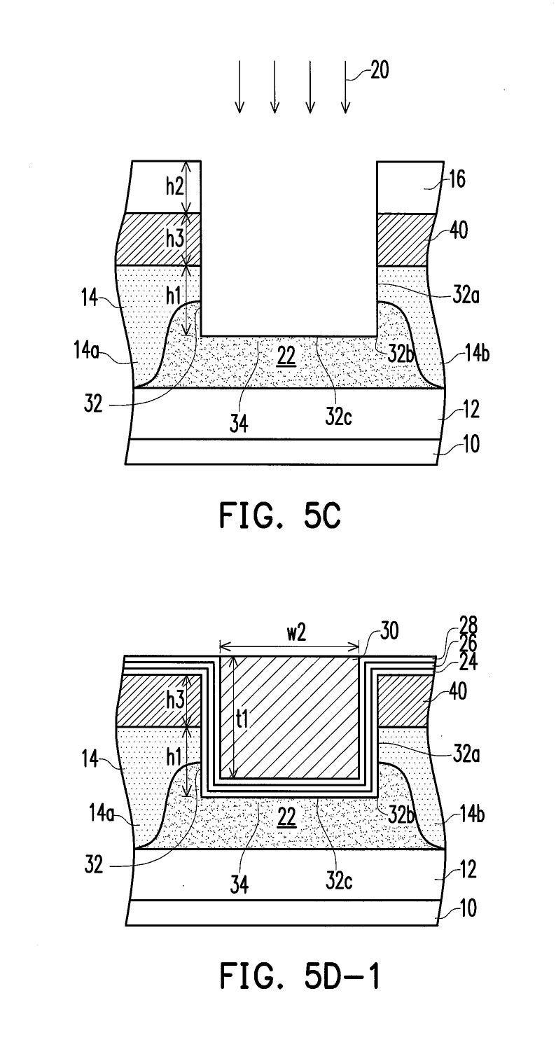

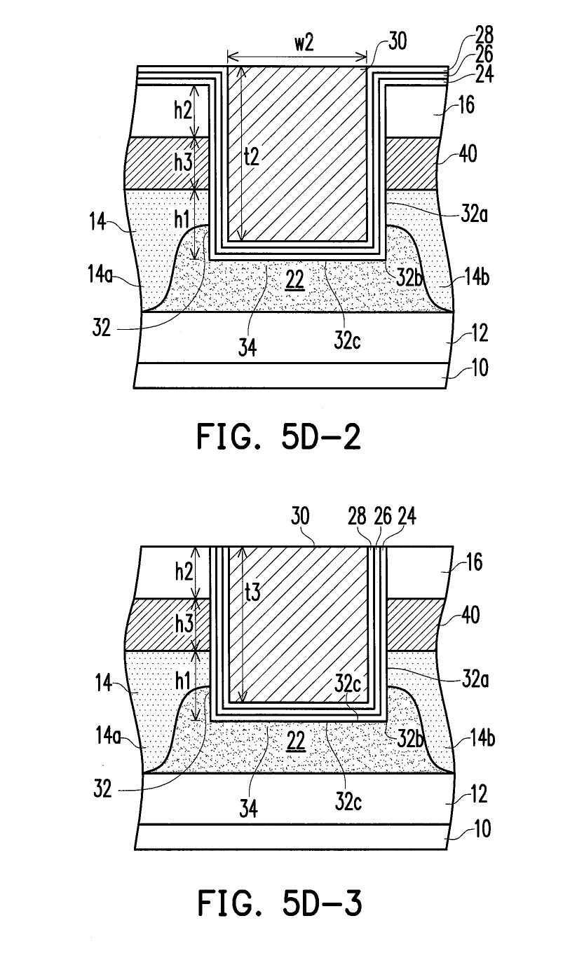

FIGS. 4A-4D-1 are cross-sectional views illustrating a fabrication method of a silicon nitride ROM according to a seventh embodiment of the invention. FIG. 4D-2 is a cross-sectional view of a silicon nitride ROM according to an eighth embodiment of the invention. FIG. 4D-3 is a cross-sectional view of a silicon nitride ROM according to a ninth embodiment of the invention. FIGS. 5A-5D-1 are cross-sectional views illustrating a fabrication method of a silicon nitride ROM according to a tenth embodiment of the invention. FIG. 5D-2 is a cross-sectional view of a silicon nitride ROM according to an eleventh embodiment of the invention. FIG. 5D-3 is a cross-sectional view of a silicon nitride ROM according to a twelfth embodiment of the invention.

The silicon nitride ROM fabrication methods illustrated in FIGS. 4A-4D-1, FIG. 4D-2, and FIG. 4D-3 are respectively similar to the silicon nitride ROM fabrication methods illustrated in FIGS. 2A-2D-1, FIG. 2D-2, and FIG. 2D-3, and the silicon nitride ROM fabrication methods illustrated in FIGS. 5A-5D-1, FIG. 5D-2, and FIG. 5D-3 are respectively similar to the silicon nitride ROM fabrication methods illustrated in FIGS. 3A-3D-1, FIG. 3D-2, and FIG. 3D-3. However, referring to FIGS. 4C, 5C, and 6C, no spacer 18 (as shown in FIGS. 2C and 3C) is formed on the sidewall 32a of the trench 32 after the trench 32 is formed in the hard mask layer 16 and the substrate 10. The second doped region 22 is directly formed in the first doped region 14 below the trench 32 through an ion implantation process 20 (for example, a vertical ion implantation process) by using the hard mask layer 16 (without the spacer 18) as a mask, and the second doped region 22 is extended downwards into the well 12, sidewards to the base angle 32b of the trench 32, and upwards to the lower sidewall 32a of the trench 32. The second doped region 22 is extended from the first doped region 14 into the well 12 to separate the first doped region 14 into a source doped region 14a and a drain doped region 14b. The second doped region 22 is extended from the bottom 32c of the trench 32 to the lower portion of the sidewall 32a of the trench 32 along the base angle 32b of the trench 32, so that the source doped region 14a and the drain doped region 14b do not cover the bottom 32c and the base angle 32b of the trench 32 but are extended from the upper portion of the sidewall 32a of the trench 32 to the surface of the substrate 10. In other words, the channel region 34 between the source doped region 14a and the drain doped region 14b is not only located at the bottom 32c of the trench 32 but also extended upwards to the lower portion of the sidewall 32a of the trench 32 along the base angle 32b of the trench 32 so that the length of the channel region 34 is extended. In addition, because the source doped region 14a and the drain doped region 14b do not cover the bottom 32c and the base angle 32b of the trench 32, when the device is in operation, a high electric field is produced at the exposed portion of the base angle 32b and accordingly the carrier injection efficiency is improved.

After the source doped region 14a and the drain doped region 14b are formed, the fabrication of the silicon nitride ROM is completed through the fabrication methods illustrated in FIGS. 2D-1, 2D-2, 2D-3, 3D-1, 3D-2, and 3D-3, and the fabricated silicon nitride ROM is as those illustrated in FIGS. 4D-1, 4D-2, 4D-3, 5D-1, 5D-2, and 5D-3.

In the embodiment described above, the second doped region 22 is formed through an ion implantation process after the trench 32 is formed and before the tunnelling dielectric layer 24 is formed, as shown in FIGS. 4C and 5C. However, the invention is not limited thereto. In an embodiment, the second doped region 22 may also be formed through an ion implantation process 20 after the tunnelling dielectric layer 24 is formed and before the charge storage dielectric layer 26 is formed. In another embodiment, the second doped region 22 may also be formed through an ion implantation process 20 after the tunnelling dielectric layer 24 and the charge storage dielectric layer 26 are formed and before the top dielectric layer 28 is formed. In still another embodiment, the second doped region 22 may also be formed through an ion implantation process 20 after the tunnelling dielectric layer 24, the charge storage dielectric layer 26, and the top dielectric layer 28 are formed and before the gate material layer is formed.

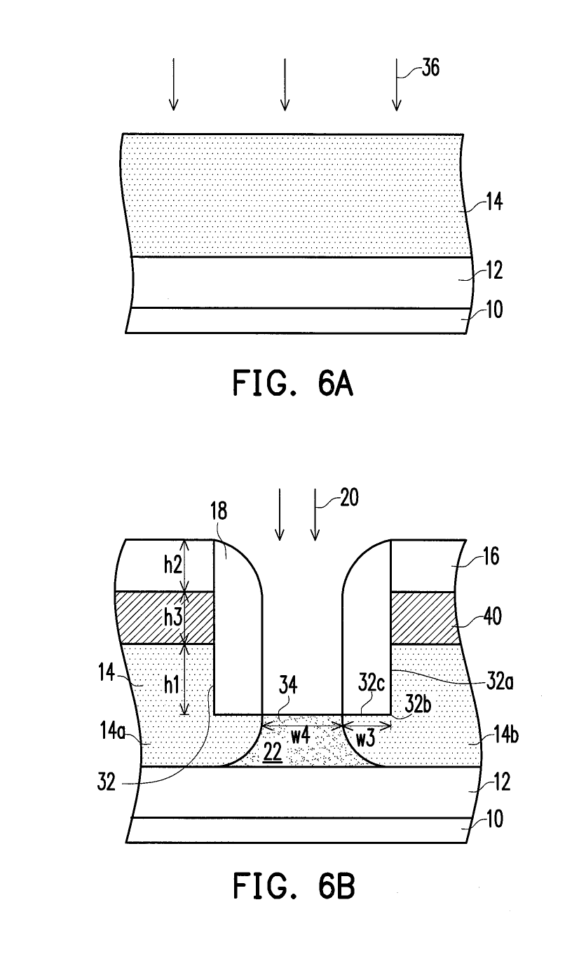

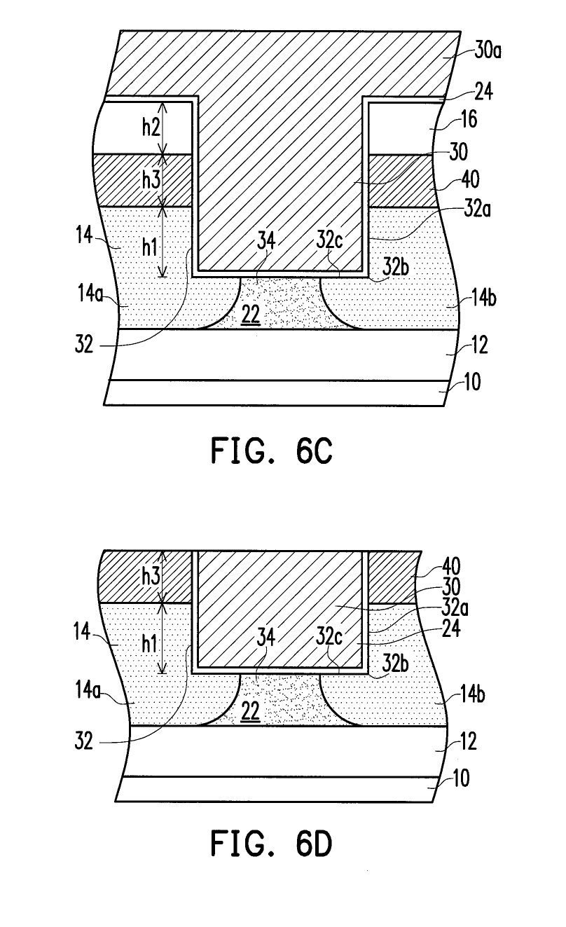

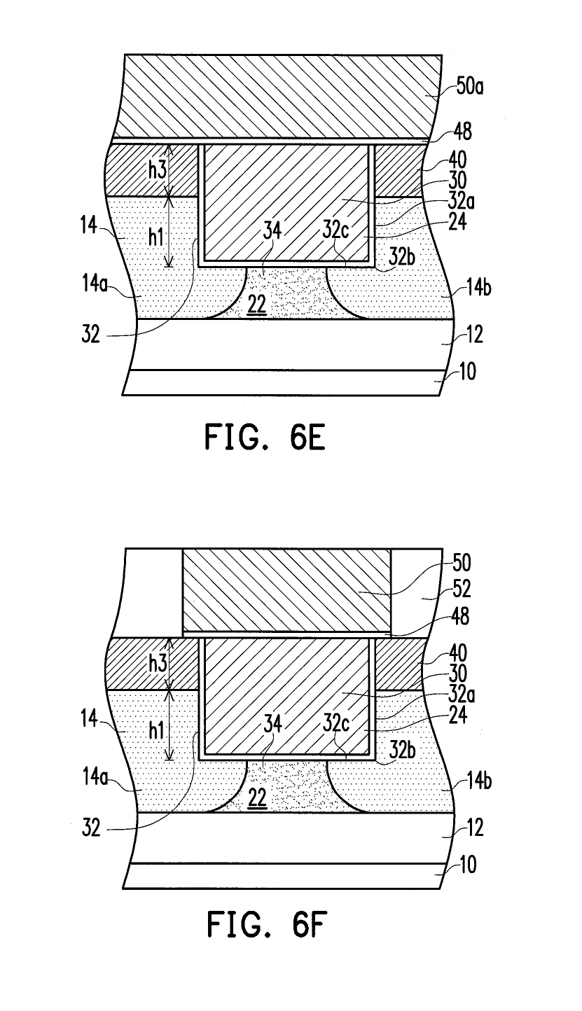

FIGS. 6A-6F are cross-sectional views illustrating a fabrication method of a flash memory cell according to a thirteenth embodiment of the invention.

Referring to FIGS. 6A and 6B, the well 12, the first doped region 14, the semiconductor layer 40, the hard mask layer 16, the trench 32, and the spacer 18 are formed through the fabrication method illustrated in FIGS. 3A-3C, and the second doped region 22 is formed below the trench 32 by using the spacer 18 and the hard mask layer 16 as a mask, so as to separate the first doped region 14 into the source doped region 14a and the drain doped region 14b.

Next, referring to FIG. 6C, the spacer 18 is also removed through the technique described above. Thereafter, a tunnelling dielectric layer 24 is formed on the hard mask layer 16 and the sidewall 32a and the bottom 32c of the trench 32. Next, a floating gate material layer 30a is formed on the substrate 10, wherein the floating gate material layer 30a covers the hard mask layer 16 and fills the trench 32. The floating gate material layer 30a may be made of doped polysilicon.

After that, referring to FIG. 6D, the floating gate material layer 30a, the tunnelling dielectric layer 24, and the hard mask layer 16 on the semiconductor layer 40 are removed through an etching process or a CMP process until the semiconductor layer 40 is exposed. The floating gate material layer 30a remaining in the semiconductor layer 40 and the trench 32 of the substrate 10 is served as a floating gate 30 of the flash memory cell. The surface of the floating gate 30 is approximately aligned with the surface of the semiconductor layer 40.

Next, referring to FIG. 6E, an inter-gate dielectric layer 48 and a control gate material layer 50a are sequentially formed on the substrate 10. The inter-gate dielectric layer 48 may be a single material layer made of a material having a high dielectric constant, such as HfO₂. The inter-gate dielectric layer 48 may also adopt a stacked double-layer structure or a stacked multi-layer structure to increase the gate coupling ratio and improve the programming and erasing efficiency. The stacked double-layer structure may be composed of a high dielectric constant material and a low dielectric constant material (indicated as high dielectric constant material/low dielectric constant material), such as silicon nitride/silicon oxide. The stacked multi-layer structure may be composed of a low dielectric constant material, a high dielectric constant material, and a low dielectric constant material (indicated as low dielectric constant material/high dielectric constant material/low dielectric constant material), such as silicon oxide/silicon nitride/silicon oxide or silicon oxide/Al₂O₃/silicon oxide. The control gate material layer 50a may be made of doped polysilicon.

Next, referring to FIG. 6F, the control gate material layer 50a and the inter-gate dielectric layer 48 are patterned. The patterned control gate material layer 50a is served as a control gate 50 of the flash memory cell. After that, an insulation layer 52 surrounding the control gate 50 and the inter-gate dielectric layer 48 is formed. The insulation layer 52 may be formed by first forming the insulation material layer (not shown) on the substrate 10 to cover the semiconductor layer 40 and the control gate 50 and then removing the insulation material layer on the control gate 50 through a planarization process, wherein the planarization process may be a CMP process.

The flash memory cell in FIG. 6F includes a substrate 10, a semiconductor layer 40, a well 12, a first doped region 14 of a first conductivity type, a second doped region 22 of a second conductivity type, a floating gate 30, a tunnelling dielectric layer 24, an inter-gate dielectric layer 48, and a control gate 50. The semiconductor layer 40 is located on the substrate 10. The well 12 and the first doped region 14 are located in the substrate 10. The semiconductor layer 40 and the first doped region 14 of the substrate 10 have a trench 32. The second doped region 22 is located at the bottom 32c of the trench 32 to separate the first doped region 14 into a source doped region 14a and a drain doped region 14b. A channel region 34 is located between the source doped region 14a and the drain doped region 14b. The floating gate 30 is located in the trench 32 of the semiconductor layer 40 and the substrate 10, and the surface of the floating gate 30 is approximately flat and aligned with the surface of the semiconductor layer 40. The tunnelling dielectric layer 24 covers the sidewall 32a and the bottom 32c of the trench 32 to separate the floating gate 30 and the substrate 10. The control gate 50 is located on the floating gate 30 and a portion of the semiconductor layer 40 around the floating gate 30. The inter-gate dielectric layer 48 is located between the control gate 50 and the floating gate 30 and between the control gate 50 and the semiconductor layer 40.

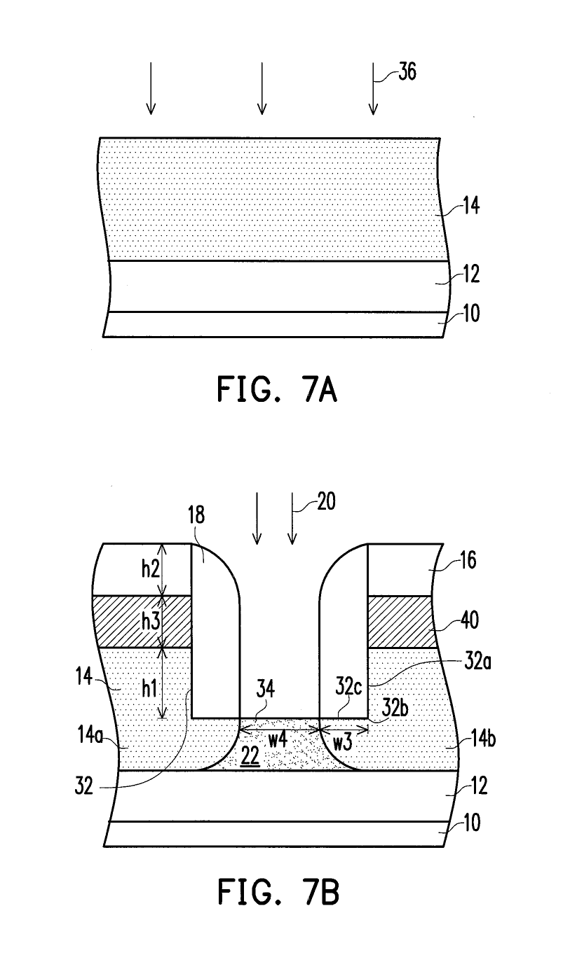

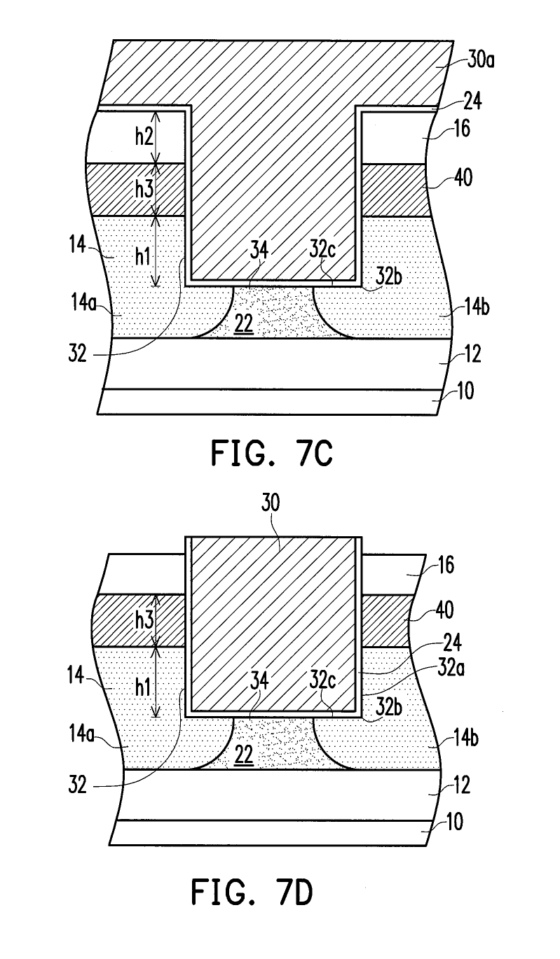

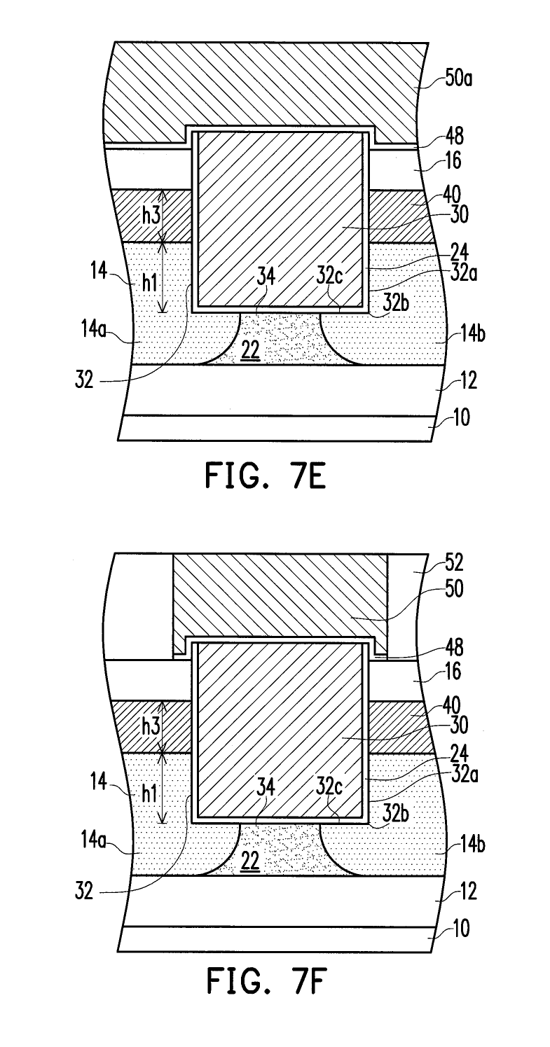

FIGS. 7A-7F are cross-sectional views illustrating a fabrication method of a flash memory cell according to a fourteenth embodiment of the invention.

The flash memory cell fabrication method illustrated in FIGS. 7A-7F is similar to that illustrated in FIGS. 6A-6F. However, referring to FIG. 7D, after the floating gate material layer 30a is formed in the trench 32, a portion of the floating gate material layer 30a is removed through an etch-back process, so as to expose the tunnelling dielectric layer 24. After that, the tunnelling dielectric layer 24 above the hard mask layer 16 is removed. Then, a portion of the floating gate material layer 30a and a portion of the hard mask layer 16 are removed by using an etching solution or an etching gas that has a lower removing rate on the floating gate material layer 30a than on the hard mask layer 16, so that the surface of the remaining floating gate material layer 30a is higher than the surface of the hard mask layer 16 and the remaining floating gate material layer 30a is served as the floating gate 30. In an embodiment, the hard mask layer 16 is made of the same material as the tunnelling dielectric layer 24, and aforementioned etch-back process is performed only once by using an etching solution or an etching gas that has a lower removing rate on the floating gate material layer 30a than on the hard mask layer 16.

Referring to FIGS. 7E and 7F, an inter-gate dielectric layer 48 and a control gate material layer 50a are sequentially formed on the substrate 10 and patterned through the method illustrated in FIGS. 6E and 6F. The patterned control gate material layer 50a is served as the control gate 50 of the flash memory cell. After that, an insulation layer 52 is formed around the control gate 50 and the inter-gate dielectric layer 48.

In the present embodiment, the surface of the floating gate is made higher than the surface of the hard mask layer so that the coupling area between the floating gate and the control gate is enlarged and accordingly the device coupling ratio is improved.

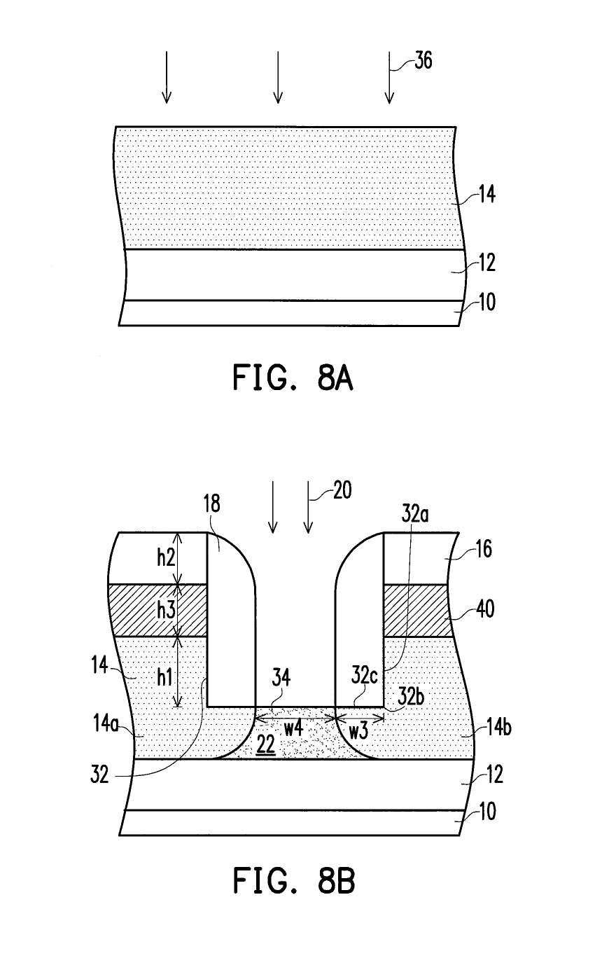

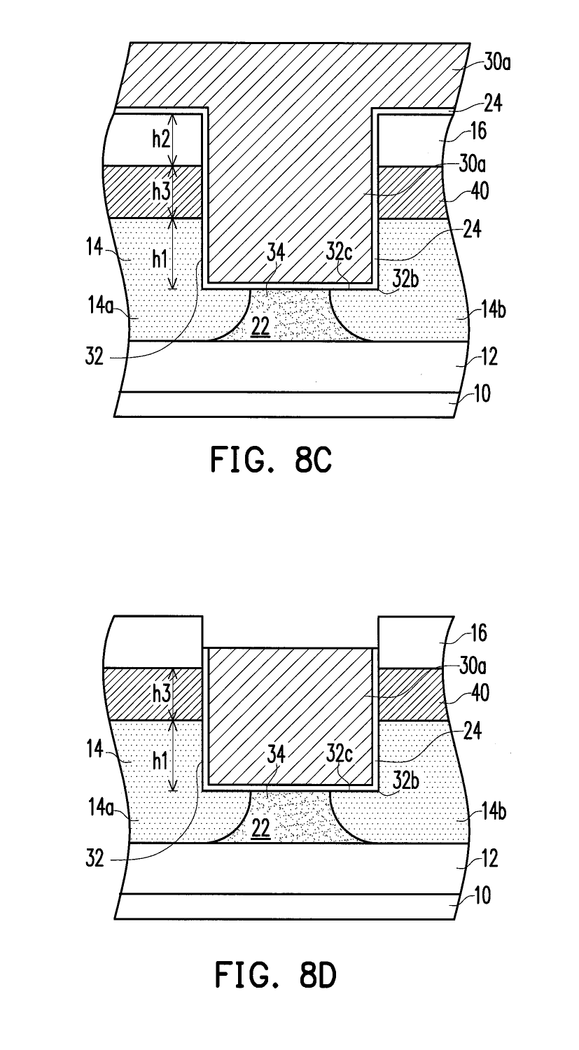

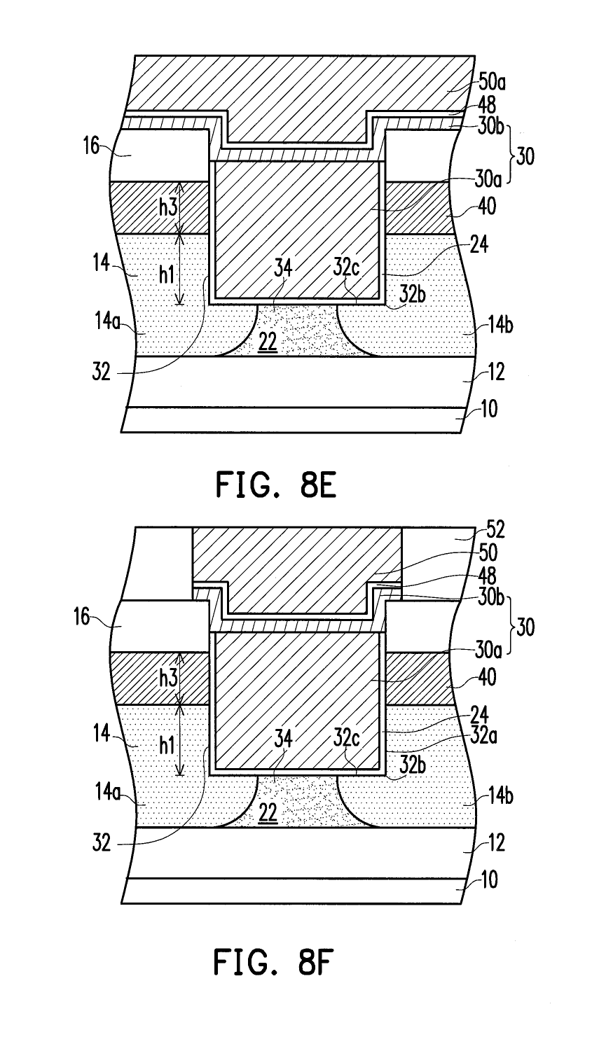

FIGS. 8A-8F are cross-sectional views illustrating a fabrication method of a flash memory cell according to a fifteenth embodiment of the invention.

The flash memory cell fabrication method illustrated in FIGS. 8A-8F is similar to that illustrated in FIGS. 6A-6F. However, referring to FIG. 8D, after the floating gate material layer 30a is formed in the trench 32, a portion of the floating gate material layer 30a is removed through an etch-back process, so as to expose the tunnelling dielectric layer 24. After that, the tunnelling dielectric layer 24 is removed. Then, a portion of the floating gate material layer 30a is removed by using an etching solution or an etching gas having a higher removing rate on the floating gate material layer 30a than on the hard mask layer 16, so as to make the surface of the remaining floating gate material layer 30a to be lower than the surface of the hard mask layer 16. In an embodiment, the hard mask layer 16 is made of the same material as the tunnelling dielectric layer 24, and aforementioned etch-back process is performed only once by using an etching solution or an etching gas having a higher removing rate on the floating gate material layer 30a than on the hard mask layer 16.

Thereafter, referring to FIGS. 8E and 8F, another floating gate material layer 30b is formed on the substrate 10 before forming the inter-gate dielectric layer 48 on the substrate 10 through the method illustrated in FIG. 6E, wherein the floating gate material layer 30b covers the hard mask layer 16 and the remaining floating gate material layer 30a in the trench 32. The floating gate material layer 30b does not fill up the trench 32 and has a groovy surface 54 in the trench 32. Next, the inter-gate dielectric layer 48 and the control gate material layer 50a are sequentially formed on the substrate 10 and patterned through the method illustrated in FIGS. 6E and 6F. The patterned floating gate material layer 30a and the floating gate material layer 30b are served as the floating gate 30.

In the present embodiment, the floating gate 30 with the groovy surface 54 is fabricated through the floating gate material layers 30a and 30b, so that the coupling area between the floating gate 30 and the control gate 50 is enlarged and accordingly the device coupling ratio is increased.

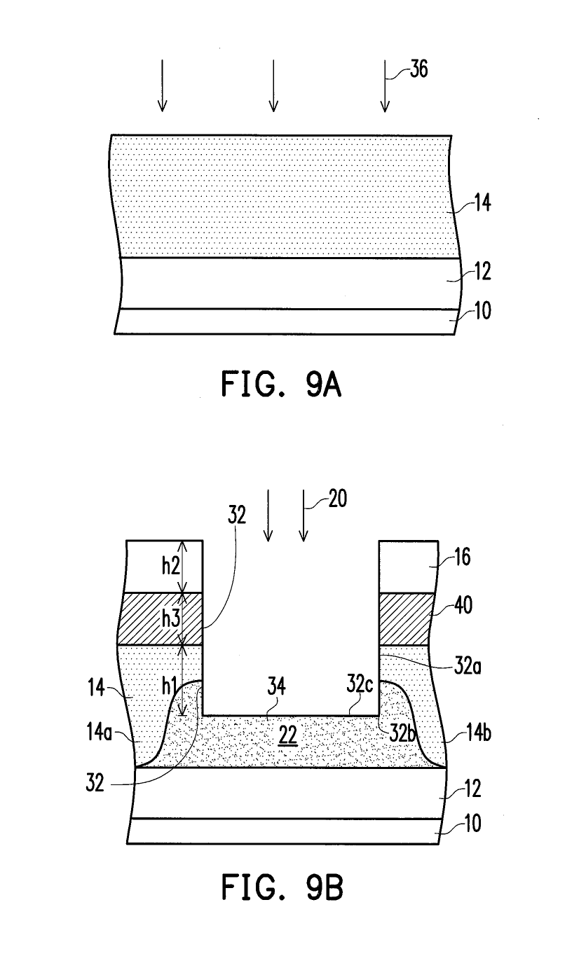

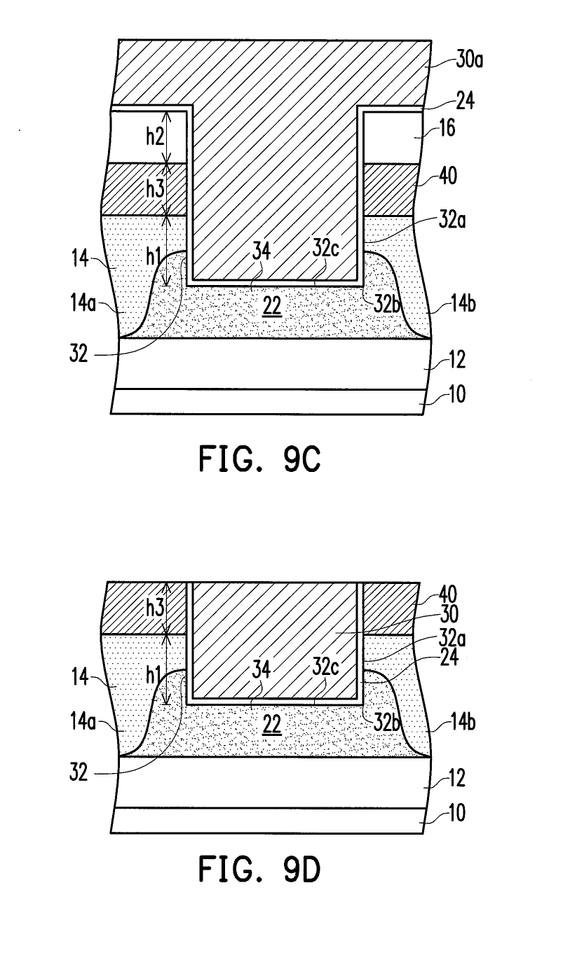

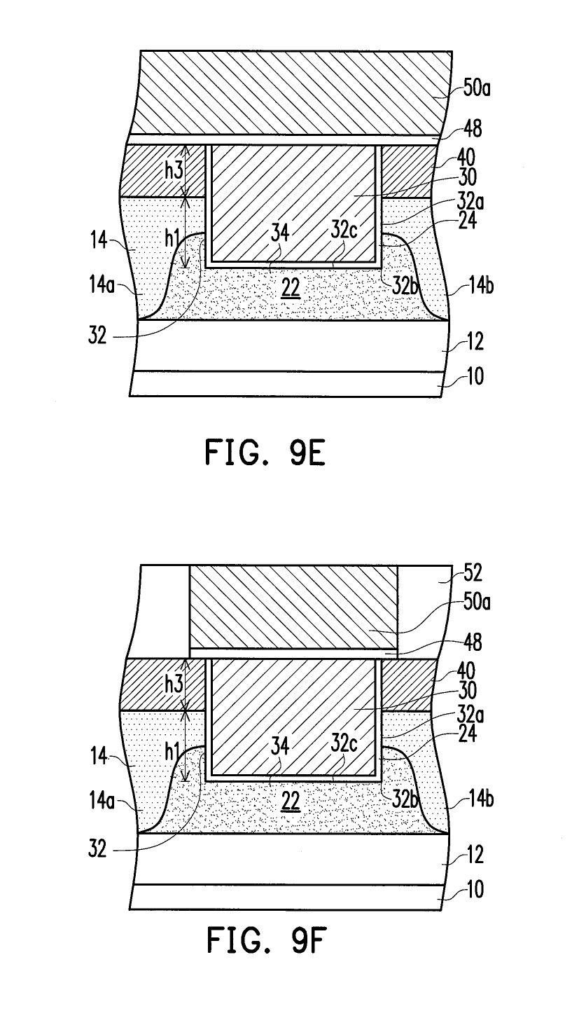

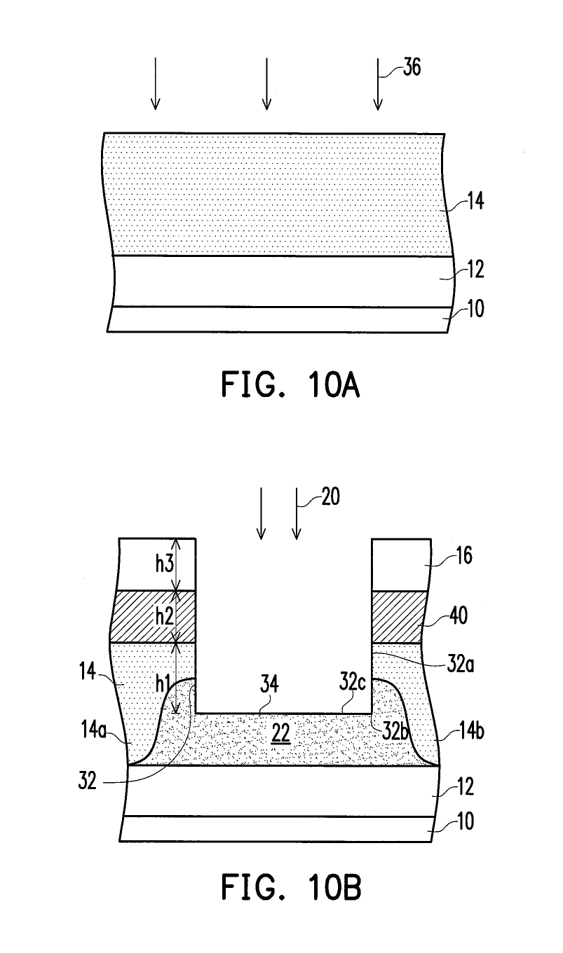

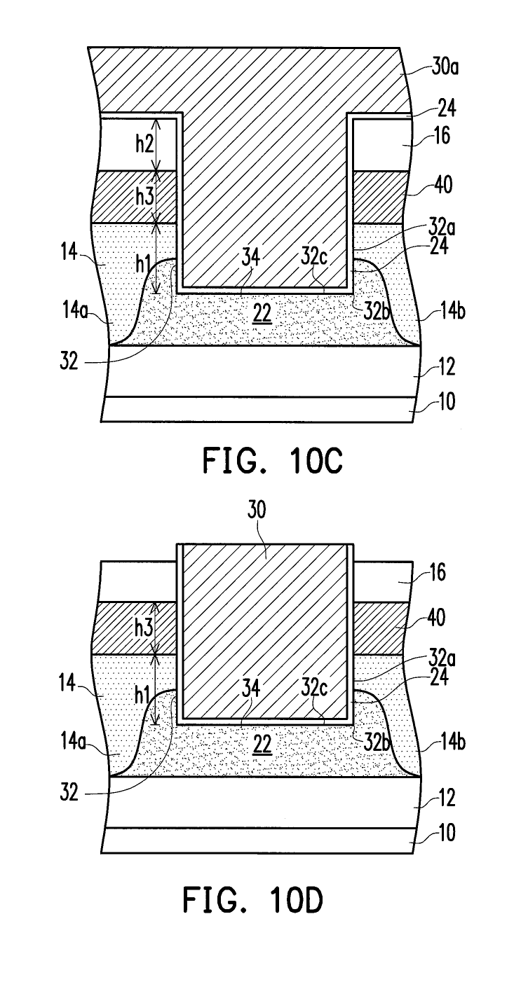

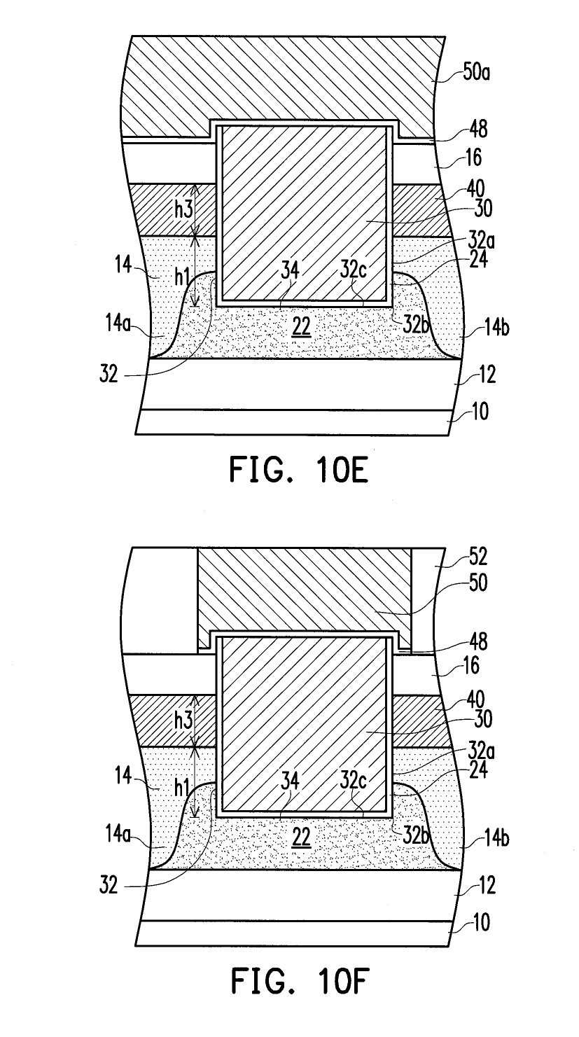

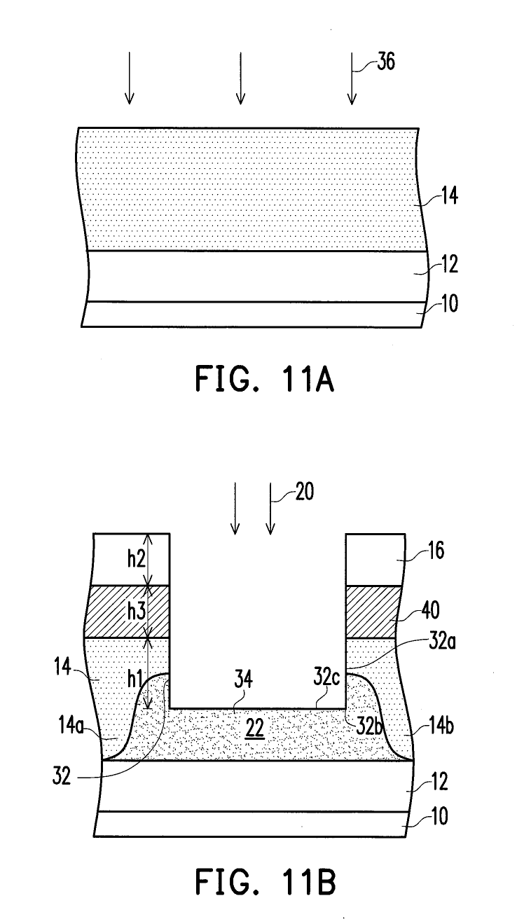

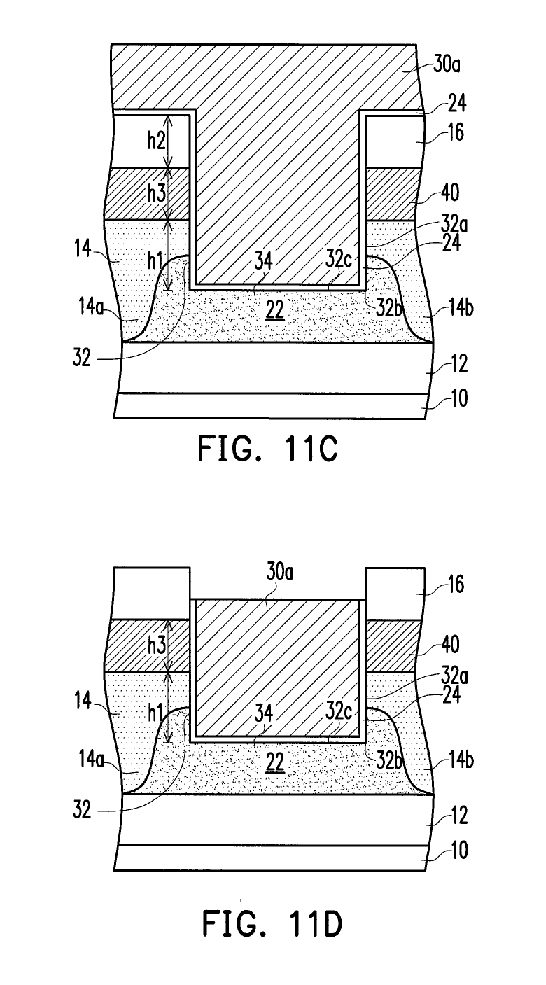

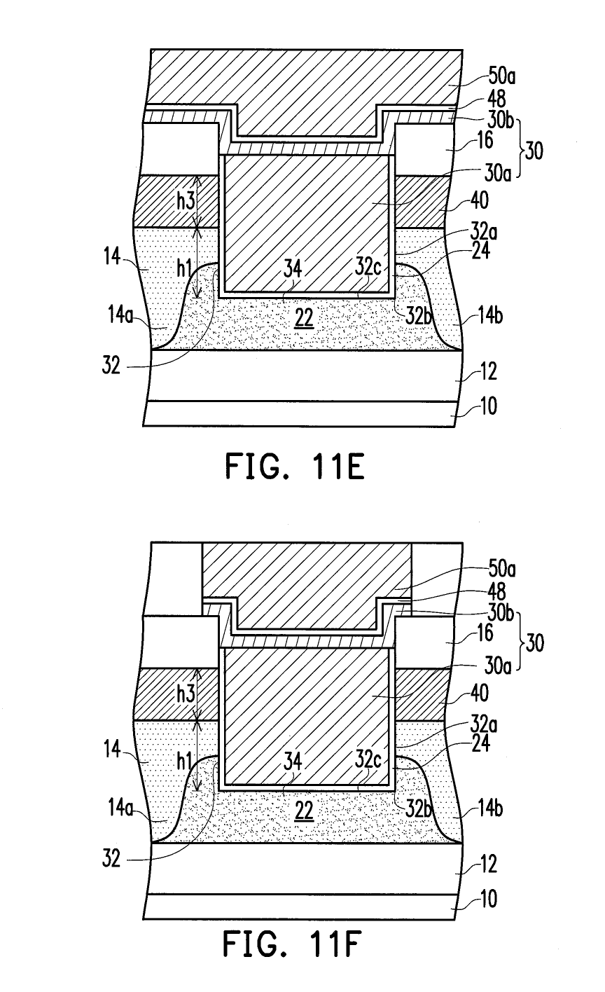

FIGS. 9A-9F are cross-sectional views illustrating a fabrication method of a flash memory cell according to a sixteenth embodiment of the invention. FIGS. 10A-10F are cross-sectional views illustrating a fabrication method of a flash memory cell according to a seventeenth embodiment of the invention. FIGS. 11A-11F are cross-sectional views illustrating a fabrication method of a flash memory cell according to an eighteenth embodiment of the invention.

The flash memory cell fabrication method illustrated in FIGS. 9A-9F is similar to that illustrated in FIGS. 6A-6F, the flash memory cell fabrication method illustrated in FIGS. 10A-10F is similar to that illustrated in FIGS. 7A-7F, and the flash memory cell fabrication method illustrated in FIGS. 11A-11F is similar to that illustrated in FIGS. 8A-8F. However, referring to FIGS. 9B, 10B, and 11B, after forming the trench 32 in the hard mask layer 16 and the substrate 10, no spacer 18 is formed on the sidewall 32a of the trench 32 (as shown in FIGS. 6B, 7B, and 8B). The second doped region 22 is directly formed in the first doped region 14 below the trench 32 through an ion implantation process 20 (for example, a vertical ion implantation process) by using the hard mask layer 16 (without the spacer 18) as a mask, and the second doped region 22 is extended downwards into the well 12, sidewards to the base angle 32b of the trench 32, and upwards to the lower sidewall 32a of the trench 32. The second doped region 22 is extended into the well 12 from the first doped region 14 to separate the first doped region 14 into a source doped region 14a and a drain doped region 14b. The second doped region 22 is further extended upwards from the bottom 32c of the trench 32 to the lower sidewall 32a of the trench 32 along the base angle 32b of the trench 32 so that the source doped region 14a and the drain doped region 14b do not cover the bottom 32c and the base angle 32b of the trench 32 but are extended from the upper sidewall 32a of the trench 32 to the surface of the substrate 10.

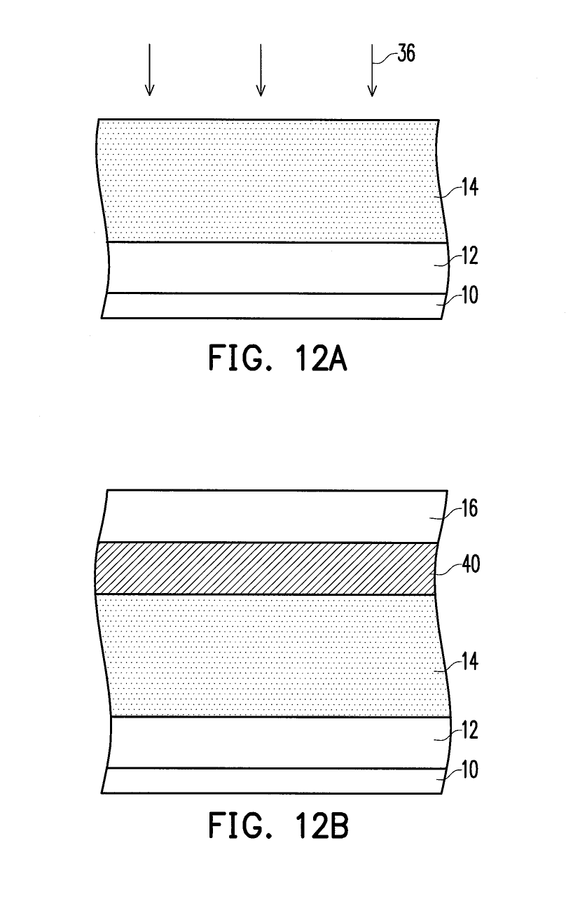

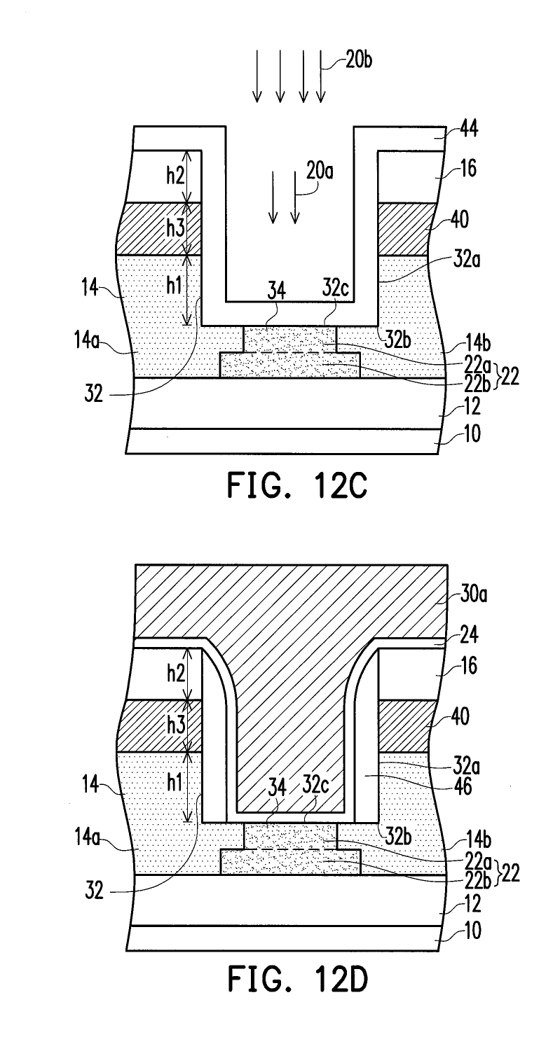

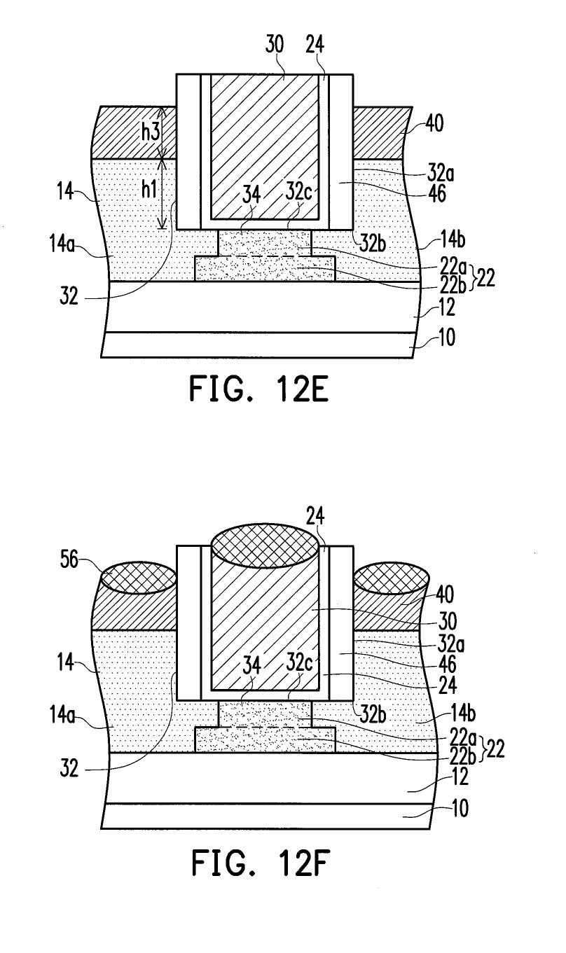

FIGS. 12A-12F are cross-sectional views illustrating a fabrication method of a metal-oxide semiconductor field-effect transistor (MOSFET) according to a nineteenth embodiment of the invention.

A spacer material layer 44 is formed after the well 12, the first doped region 14, the semiconductor layer 40, the hard mask layer 16, and the trench 32 are formed through the fabrication method illustrated in FIGS. 3A-3C. Then, the second doped region 22 is formed below the trench 32 by using the spacer material layer 44 and the hard mask layer 16 as a mask, so as to separate the first doped region 14 into the source doped region 14a and the drain doped region 14b. However, in the present embodiment, the second doped region 22 includes a first region 22a and a second region 22b that have the same conductivity type but different depths, wherein the first region 22a is closer to the bottom 32c of the trench 32, the second region 22b is farther away from the bottom 32c of the trench 32, and the surface area of the second region 22b is greater than the surface area of the first region 22a so that the source doped region 14a and the drain doped region 14b present a stepped shape. The first region 22a and the second region 22b of the second doped region 22 may be formed through ion implantation processes and the adjustment of ion energy. The ion implantation process 20a for forming the first region 22a of the second doped region 22 has a lower ion implantation energy, while the ion implantation process 20b for forming the second region 22b has a higher ion implantation energy. In an embodiment, the first doped region 14 is N-type, and the second doped region 22 is P-type. The ions implanted into the first region 22a of the second doped region 22 may be BF₂, the ion implantation energy may be about 1 KeV, and the dosage may be about 6×10¹⁴/cm². The ion implantation energy of the second region 22b may be about 10 KeV, and the dosage may be about 3×10¹⁴/cm².

Thereafter, referring to FIG. 12D, the spacer material layer 44 is anisotropically etched to form a spacer 46 on the sidewall 32a of the trench 32. Then, the gate dielectric layer 24 is formed on the substrate 10. The gate dielectric layer 24 may be made of one or a combination of silicon oxide, silicon nitride, silicon oxynitride, and a high dielectric constant material. After that, the gate material layer 30a is formed in the trench 32. The gate material layer 30a may be made of doped polysilicon, metal, or a combination of doped polysilicon and metal.

Thereafter, referring to FIG. 12E, the gate material layer 30a and the gate dielectric layer 24 on the hard mask layer 16 are removed. The remaining gate material layer 30a is served as the gate 30. The gate material layer 30a and the gate dielectric layer 24 on the hard mask layer 16 may be removed through a CMP process or an etch-back process by using the hard mask layer 16 as a stop layer. Next, the hard mask layer 16 is removed to expose the semiconductor layer 40. The hard mask layer 16 may be removed through an etching process, such as a dry etching process or a wet etching process.

After that, referring to FIG. 12F, a self-aligned silicidation process is performed to form a metal silicide 56 on the surfaces of the semiconductor layer 40 and the gate 30. The metal silicide 56 may be made of the silicide of a refractory metal, such as nickel, cobalt, titanium, copper, molybdenum, tantalum, tungsten, erbium, zirconium, platinum, or an alloy of foregoing metals.

In summary, in the embodiments of the invention described above, the gate is buried into the substrate and the source doped region and the drain doped region are also fabricated in the substrate, so that the source doped region and the drain doped region with raised effect can be fabricated through the position change of the gate in the vertical direction. Because the portions of the source doped region and the drain doped region below the gate are very shallow, a shallow junction depth can be achieved, and accordingly the production of short channel effect can be avoided. On the other hand, because the source doped region and the drain doped region are further extended to cover the sidewall of the gate, the resistances of the raised source and drain can be reduced. Moreover, a heavily doped semiconductor layer may be further formed within the source doped region and the drain doped region to further reduce the contact resistance.

In the embodiments of the invention described above, the second doped region for separating the source doped region and the drain doped region is extended upwards from the bottom of the trench to the lower sidewall of the trench along the base angle of the trench, so that the source doped region and the drain doped region do not cover the bottom and the base angle of the trench. Accordingly, the length of the channel region is extended, and because a high electric field is produced at the exposed portion of the base angle when the device is in operation, the carrier injection efficiency is improved.

Furthermore, in the embodiments of the invention described above, because the annealing process of the source doped region and the drain doped region (the first doped region) is performed before the dielectric layer (the tunnelling dielectric layer) and the gate are formed, the stability of the dielectric layer (the tunnelling dielectric layer) and the gate is ensured and won't be affected by the annealing process of the source doped region and the drain doped region (the first doped region).

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. A semiconductor device, comprising:
a first doped region of a first conductivity type, located in a substrate, having a trench;
a second doped region of a second conductivity type, located at a bottom of the trench, separating the first doped region into a source doped region and a drain doped region, wherein a channel region is located between the source doped region and the drain doped region;
a gate, located in the trench; and
a dielectric layer, located between the gate and the substrate within the trench.

2. The semiconductor device according to claim 1, wherein the source doped region or the drain doped region is extended from a spot on the bottom of the trench that is close to a base angle to a surface of the substrate along a sidewall of the trench.

3. The semiconductor device according to claim 2, wherein the second doped region comprises a first region and a second region having different depths, wherein an area of the second region that is farther away from the bottom of the trench is greater than an area of the first region that is closer to the bottom of the trench, so that the source doped region or the drain doped region presents a stepped shape.

4. The semiconductor device according to claim 2 further comprising a spacer, wherein the spacer is located between the dielectric layer on the sidewall of the trench and the substrate.

5. The semiconductor device according to claim 1, wherein the second doped region is extended from the bottom of the trench to a spot on the sidewall of the trench that is close to the base angle so that the source doped region or the drain doped region does not cover the bottom of the trench or the base angle but is extended from the sidewall of the trench to the surface of the substrate.

6. The semiconductor device according to claim 1 further comprising a semiconductor layer, wherein the semiconductor layer completely covers and is in contact with the source doped region or the drain doped region.

7. The semiconductor device according to claim 6, wherein the semiconductor layer comprises a doped single-crystal silicon layer, a doped polysilicon layer, a doped epi-silicon layer, a doped GeSi layer or a combination thereof.

8. The semiconductor device according to claim 6 further comprising a metal silicide layer, wherein the metal silicide layer is located on the semiconductor layer.

9. The semiconductor device according to claim 6 further comprising a hard mask layer, wherein the hard mask layer is located on the semiconductor layer.

10. The semiconductor device according to claim 1 further comprising a hard mask layer, wherein the hard mask layer is located on the source doped region or the drain doped region.

11. The semiconductor device according to claim 1, wherein the dielectric layer is further extended onto the source doped region or the drain doped region.

12. The semiconductor device according to claim 1, wherein the gate is further extended above and covers the source doped region or the drain doped region.

13. The semiconductor device according to claim 1, wherein the semiconductor device is a metal-oxide semiconductor field-effect transistor (MOSFET), and the dielectric layer is a gate dielectric layer.

14. The semiconductor device according to claim 1, wherein the semiconductor device is a non-volatile memory cell, and the dielectric layer is a tunnelling dielectric layer.

15. The semiconductor device according to claim 14, wherein the gate is a floating gate, and the semiconductor device further comprises:
a control gate, located above the floating gate; and
an inter-gate dielectric layer, located between the floating gate and the control gate.

16. The semiconductor device according to claim 15, wherein the floating gate is protruded from the surface of the substrate.

17. The semiconductor device according to claim 15, wherein the floating gate, the inter-gate dielectric layer, and the control gate are further extended above the source doped region or the drain doped region.

18. The semiconductor device according to claim 15, wherein a surface of the floating gate is a flat surface or a surface with grooves.

19. The semiconductor device according to claim 14 further comprising a charge storage dielectric layer, wherein the charge storage dielectric layer is located between the tunnelling dielectric layer and the gate.

20. The semiconductor device according to claim 19, wherein the charge storage dielectric layer is further extended above the source doped region or the drain doped region.

21. The semiconductor device according to claim 19 further comprising a top dielectric layer, wherein the top dielectric layer is located between the charge storage dielectric layer and the gate.

22. A fabrication method of a semiconductor device, comprising:
providing a substrate;
forming a first doped region of a first conductivity type in the substrate;
removing a portion of the first doped region to form a trench in the first doped region;
forming a second doped region of a second conductivity type at a bottom of the trench to separate the first doped region into a source doped region and a drain doped region;
forming a gate in the trench; and
forming a dielectric layer between the gate and the substrate within the trench.

23. The fabrication method according to claim 22 further comprising forming a spacer on a sidewall of the trench.

24. The fabrication method according to claim 23, wherein the formation method of the second doped region comprises performing a single ion implantation process by using the spacer as a mask, so as to extend the source doped region and the drain doped region from a surface of the substrate to a spot on the bottom of the trench that is close to a base angle along the sidewall of the trench.

25. The fabrication method according to claim 23, wherein the formation method of the second doped region comprises performing a first ion implantation process and a second ion implantation process by using the spacer as a mask, wherein a energy of the second ion implantation process is higher than a energy of the first ion implantation process so that an area of a region formed through the second ion implantation process that is farther away from the bottom of the trench is greater than an area of a region formed through the first ion implantation process that is closer to the bottom of the trench.

26. The fabrication method according to claim 23, wherein after forming the second doped region and before forming the dielectric layer, the fabrication method further comprises removing the spacer.

27. The fabrication method according to claim 22, wherein the formation method of the second doped region comprises performing an ion implantation process by using the trench as a mask so as to extend the second doped region from the bottom of the trench to a spot on the sidewall of the trench that is close to the base angle.

28. The fabrication method according to claim 22 further comprising forming a semiconductor layer on the substrate before forming the trench, wherein the semiconductor layer is in contact with the first doped region.

29. The fabrication method according to claim 28 further comprising forming a hard mask layer on the semiconductor layer after forming the semiconductor layer and before forming the trench.

30. The fabrication method according to claim 29 further comprising removing the hard mask layer after forming the trench and before forming the dielectric layer.

31. The fabrication method according to claim 29 further comprising removing the hard mask layer after forming the gate.

32. The fabrication method according to claim 29 further comprising forming a metal silicide layer on the semiconductor layer after removing the hard mask layer.

33. The fabrication method according to claim 22 further comprising forming a hard mask layer on the substrate before forming the trench.

34. The fabrication method according to claim 33 further comprising removing the hard mask layer before forming the dielectric layer.

35. The fabrication method according to claim 22, wherein the semiconductor device is a MOSFET, and the dielectric layer is a gate dielectric layer.

36. The fabrication method according to claim 22, wherein the semiconductor device is a non-volatile memory cell, and the dielectric layer is a tunnelling dielectric layer.

37. The fabrication method according to claim 22, wherein the gate is a floating gate, and the fabrication method further comprises:
forming a control gate on the floating gate; and
forming an inter-gate dielectric layer between the floating gate and the control gate.

38. The fabrication method according to claim 22 further comprising:
forming a hard mask layer on the substrate before forming the trench;
making an upper surface of the gate in the trench to be lower than an upper surface of the hard mask layer, so as to expose a sidewall of the hard mask layer;
forming a gate material layer on the sidewall of the hard mask layer and the gate, so as to form a floating gate having a groovy surface;
forming a control gate on the floating gate; and
forming an inter-gate dielectric layer between the floating gate and the control gate.

39. The fabrication method according to claim 37, wherein the floating gate, the inter-gate dielectric layer, and the control gate are further extended above the source doped region and the drain doped region.

40. The fabrication method according to claim 36 further comprising forming a charge storage dielectric layer between the tunnelling dielectric layer and the gate.

41. The fabrication method according to claim 40, wherein the charge storage dielectric layer is further extended above the source doped region and the drain doped region.

42. The fabrication method according to claim 40 further comprising forming a top dielectric layer between the charge storage dielectric layer and the gate.
